(19) United States
(12) Patent Application Publication
(10) Pub. No.: US 2016/0276342 A1
(43) Pub. Date: Sep. 22, 2016

(54) SEMICONDUCTOR DEVICES INCLUDING SHALLOW TRENCH ISOLATION (STI) LINERS

(71) Applicant: Samsung Electronics Co., Ltd., Suwon-si (KR)

(72) Inventors: Sun-Me LIM, Yongin-si (KR); Young-Dal LIM, Suwon-si (KR); Hag-Ju CHO, Seongnam-si (KR)

(21) Appl. No.: 14/988,039

(22) Filed: Jan. 5, 2016

(30) Foreign Application Priority Data
Mar. 18, 2015 (KR) 10-2015-0037177

(51) Int. Cl. H01L 27/088; H01L 29/423; H01L 27/12; H01L 29/78; H01L 29/06

(52) U.S. Cl. CPC H01L 27/0886; H01L 29/785; H01L 29/0653; H01L 27/1211; H01L 29/42356

(57) ABSTRACT

Semiconductor devices including STI liners are provided. The semiconductor devices may include a STI trench that defines an active region in a substrate, a STI liner that extends conformally along side walls and a bottom surface of the STI trench, a device isolation film that is on the STI liner and fills up at least a part of the STI trench, a first gate structure that is disposed on the active region, and a second gate structure that is spaced apart from the first gate structure. The second gate structure may include a gate insulating film contacting the device isolation film, a gate electrode on the gate insulating film, and spacers on both sides of the gate electrode. Lower surfaces of the spacers may contact an upper surface of the STI liner.

### CROSS-REFERENCE TO RELATED APPLICATION

This U.S. non-provisional patent application claims priority under 35 U.S.C. §119 to Korean Patent Application No. 10-2015-0037177 filed on Mar. 18, 2015 in the Korean intellectual Property Office, the disclosure of which is hereby incorporated by reference in its entirety.

### BACKGROUND

1. Technical Field

The present inventive concept relates to a semiconductor device having a STI liner.

2. Discussion of Related Art

Recently, semiconductor devices have been developed to provide a high-speed operation at a low voltage, and manufacturing processes of a semiconductor device have been developed to increase integration degree.

The increased integration degree of the device may cause a short channel effect or the like on a field effect transistor (FET) as one of a semiconductor device. Therefore, in order to overcome this problem, researches of a fin field effect transistor (Fin FET) in which channels are formed by a three-dimensional spatial structure have been actively conducted.

Also, it is possible to utilize an epitaxial process when forming a source or a drain so as to apply a tensile stress or a compressive stress to the channel of the transistor for improving the operating characteristics of the transistor. However, there has been a problem that, in the process of removing the native oxide before growth of an epitaxial layer, a part of a device isolation film (shallow trench isolation; hereinafter, referred to as STI) adjacent to the source or the drain is etched together, and thus, defects may occur.

### SUMMARY

Aspects of the present inventive concept provide a semiconductor device which is capable of reducing or possibly preventing an occurrence of defect in the transistor, by possibly preventing the device isolation film (STI) from being etched together, when removing the native oxide in the epitaxial growth process of the semiconductor device.

The aspects of the present inventive concept are not limited to the above-mentioned aspects, and another aspect that has not been mentioned will be clearly understood by those skilled in the art from the following description.

According to some embodiments of the present inventive concept, a semiconductor device may include a STI trench which defines an active region formed in a substrate, a STI liner which is formed conformally along side walls and a bottom surface of the STI trench, a device isolation film which is formed on the STI liner and fills up at least a part of the STI trench, a first gate structure which is disposed on the active region, and a second gate structure which is spaced apart from the first gate structure, wherein the second gate structure includes a gate insulating film being in contact with the device isolation film, a gate electrode located on the gate insulating film, and spacers disposed on both sides of the gate electrode, and lower surfaces of the spacers are formed so as to be in contact with the upper surface of the STI liner.

According to some embodiments of the present inventive concept, a semiconductor device may include a plurality of fins that extends in a first direction on a substrate, a first gate structure and a second gate structure which extend in a second direction intersecting with the plurality of fins and are spaced apart from each other, a STI trench which is formed among the plurality of fins, a STI liner which is conformally formed along a part of side walls and a bottom surface of the STI trench, and a device isolation film which is formed on the STI liner and fills up at least a part of the STI trench, wherein the second gate structure includes a gate insulating film, a gate electrode, and spacers located on both sides of the gate electrode, and the spacers of the second gate structure include a first spacer part formed on one side of the gate electrode of the second gate structure, and a second spacer part formed on the other side of the gate electrode, and the first spacer part is in contact with any one upper surface of the plurality of fins, and the second spacer part is in contact with an upper surface of the device isolation film.

According to some embodiments of the present inventive concept, a semiconductor device may include a substrate which includes a first region and a second region, a plurality of fins that extends in a first direction on the first region or the second region, a STI trench which is formed among the plurality of fins, a gate structure which intersects with the plurality of fins and extends in a second direction different from the first direction, a DTI trench which is formed between the first region and the second region, a DTI liner which is conformally formed along side walls and a bottom surface of the DTI trench, and a device isolation film which is formed on the DTI liner and fills up at least a part of the DTI trench, wherein a lower surface of the STI trench is formed higher than a lower surface of the DTI trench.

### BRIEF DESCRIPTION OF THE DRAWINGS

The above and other aspects and features of the present inventive concept will become more apparent by describing in detail example embodiments thereof with reference to the attached drawings, in which:

FIG. 1 is a diagram for explaining a semiconductor device according to a first embodiment of the present inventive concept;

FIGS. 2 and 3 are cross-sectional views taken along a line A-A of FIG. 1;

FIG. 4 is a diagram for explaining a semiconductor device according to a second embodiment of the present inventive concept;

FIG. 5 is a cross-sectional view taken along a line B-B of FIG. 4;

FIG. 6 is a diagram for explaining a semiconductor device according to a third embodiment of the present inventive concept;

FIG. 7 is a cross-sectional view taken along a line C-C of FIG. 4;

FIG. 8 is a diagram for explaining a semiconductor device according to a fourth embodiment of the present inventive concept;

FIG. 9 is a cross-sectional view taken along a line Y-Y of FIG. 8;

FIG. 10 is a cross-sectional view taken along a line X-X of FIG. 8;

FIGS. 11 and 12 are diagrams for explaining a semiconductor device according to a fifth embodiment of the present inventive concept;

FIGS. 13 and 14 are diagrams for explaining a semiconductor device according to a sixth embodiment of the present inventive concept;

FIGS. 15 and 16 are diagrams for explaining a semiconductor device according to a seventh embodiment of the present inventive concept;

FIG. 17 is a diagram for explaining a semiconductor device according to an eighth embodiment of the present inventive concept;

FIG. 18 is a cross-sectional view taken along a line Y-Y of FIG. 17;

FIG. 19 is a cross-sectional view taken along a line X-X of FIG. 17;

FIGS. 20 and 21 are diagrams for explaining a semiconductor device according to a ninth embodiment of the present inventive concept;

FIGS. 22 and 23 are diagrams for explaining a semiconductor device according to a tenth embodiment of the present inventive concept;

FIG. 24 is a diagram for explaining a semiconductor device according to some embodiments of the present inventive concept;

FIG. 25 is a diagram for explaining a semiconductor device according to some embodiments of the present inventive concept;

FIG. 26 is a block diagram of a SoC system including a semiconductor device according to some embodiments of the present inventive concept;

FIG. 27 is a block diagram of an electronic system including a semiconductor device according to some embodiments of the present inventive concept;

FIGS. 28 to 30 are semiconductor systems including a semiconductor device according to some embodiments of the present inventive concept; and

FIGS. 31 to 40 are diagrams illustrating a method of manufacturing a semiconductor device according to some embodiments of the present inventive concept.

### DETAILED DESCRIPTION

Advantages and features of the present inventive concept and methods of accomplishing the same may be understood more readily by reference to the following detailed description of embodiments and the accompanying drawings. The present inventive concept may, however, be embodied in many different forms and should not be construed as being limited to the embodiments set forth herein. Rather, these embodiments are provided so that this disclosure will be thorough and complete and will fully convey the concept of the inventive concept to those skilled in the art, and the present inventive concept will only be defined by the appended claims. Like reference numerals refer to like elements throughout the specification.

The terminology used herein is for the purpose of describing particular embodiments only and is not intended to be limiting of the inventive concept. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on”, “directly connected to” or “directly coupled to” another element or layer, there are no intervening elements or layers present. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive concept.

Spatially relative terms, such as “beneath”, “below”, “lower”, “above”, “upper”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

Embodiments are described herein with reference to cross-section illustrations that are schematic illustrations of idealized embodiments (and intermediate structures). As such, variations from the shapes of the illustrations as a result, for example, of manufacturing techniques and/or tolerances, are to be expected. Thus, these embodiments should not be construed as limited to the particular shapes of regions illustrated herein but are to include deviations in shapes that result, for example, from manufacturing. For example, an implanted region illustrated as a rectangle will, typically, have minded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concept.

Unless otherwise defined, all terms (including technical and scientific terms) used herein have the same meaning as commonly understood by one of ordinary skill in the art to which the present inventive concept belongs. It will be further understood that terms, such as those defined in commonly used dictionaries, should be interpreted as having a meaning that is consistent with their meaning in the context of the relevant art and this specification and will not be interpreted in an idealized or overly formal sense unless expressly so defined herein.

Hereinafter, example embodiments of the inventive concept will be described in detail with reference to the accompanying drawings.

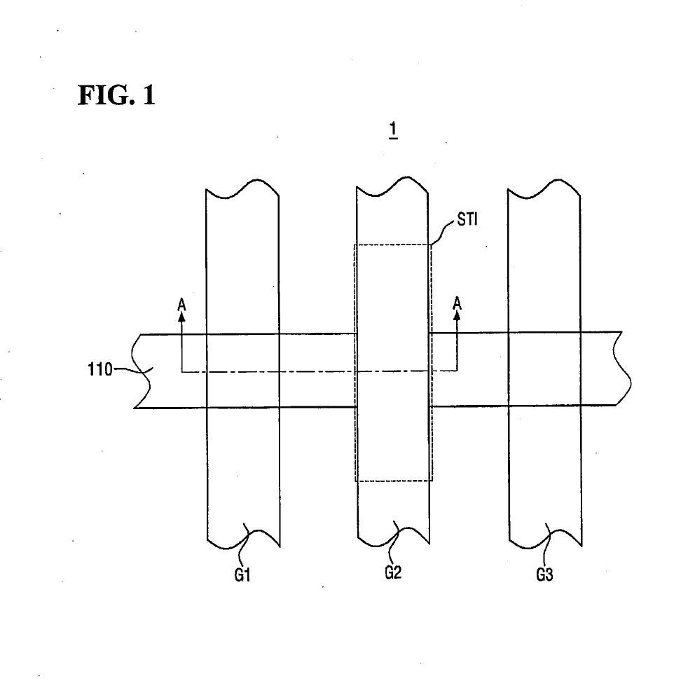

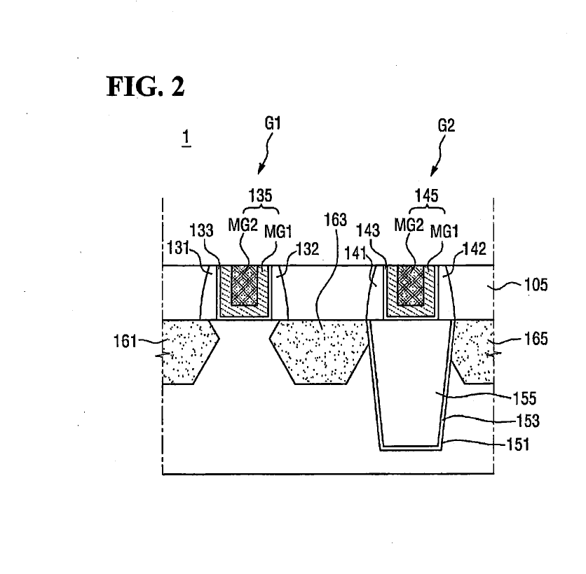

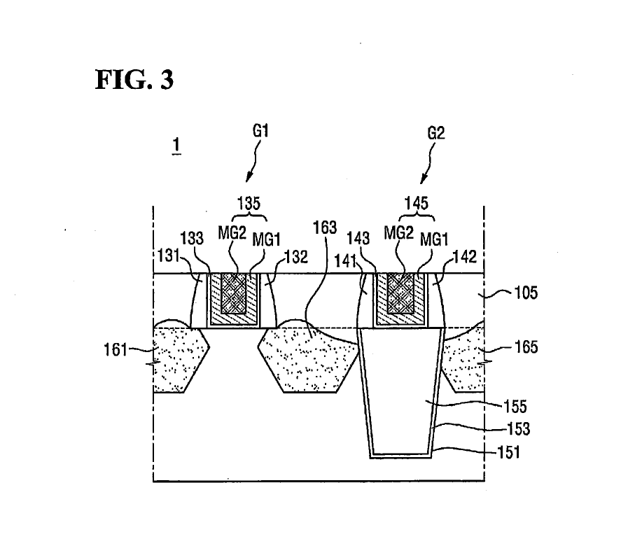

FIG. 1 is a diagram for explaining a semiconductor device according to a first embodiment of the present inventive concept. FIGS. 2 and 3 are cross-sectional views taken along a line A-A of FIG. 1.

Referring to FIG. 1, a semiconductor device 1 includes a substrate 100, an active region 110, a first gate structure G1, a second gate structure G2 and a device isolation film (STI) 155.

The substrate 100, for example, may be a semiconductor substrate. The substrate 100 may include one of silicon, strained silicon, silicon alloy, silicon carbide (SiC), silicon germanium (SiGe), silicon germanium carbide (SiGeC), germanium, germanium alloy, gallium arsenide (GaAs), indium arsenide (InAs), an III-V semiconductor, and an II-VI semiconductor, combinations thereof, and laminations thereof. Also, if necessary, the substrate may be an organic plastic substrate rather than the semiconductor substrate. Hereinafter, the substrate 100 will be described as being made up of silicon.

The substrate 100 may be a P type and may be an N type. Meanwhile, in some embodiments of the present inventive concept, an insulating substrate may be used as the substrate 100. Specifically, it is possible to use silicon on insulator (SOI) substrate. When using the SOI substrate, there is an advantage that may reduce the delay time in the operating process of the semiconductor device 1.

The active region 110 may be defined by a field insulating film, such as the device isolation film (STI) 155, within the substrate 100. As illustrated in FIG. 1, although the active region 110 may extend in a first direction, the present inventive concept is not limited thereto.

The first gate structure G1 and the second gate structure G2 may extend in a second direction intersecting with the first direction. Specifically, the first gate structure G1 may overlap the active region 110, and the second gate structure G2 may overlap the device isolation film 155. The first gate structure G1 and the second gate structure G2 may be formed so as to extend in the same direction.

The device isolation film 155 may be formed in the substrate 100 to define the active region 110. Since the device isolation film 155 has excellent device isolation characteristics and occupies a small area, it may be formed of, but not limited to, a shallow trench isolation (STI) structure advantageous for high integration. The device isolation film 155, for example, may include at least one of silicon oxide, silicon nitride, silicon oxynitride and combinations thereof.

Referring to FIG. 2, in the semiconductor device 1, a STI trench 151 may be formed on the substrate 100, and a STI liner 153 and the device isolation film 155 may be disposed in the STI trench 151.

Specifically, the STI trench 151 may define the active region 110 formed in the substrate 100. The STI trench 151 may be formed at a constant depth and may be formed in a tapered shape in which its width becomes wider as it goes from the top to the bottom. However, the present inventive concept is not limited to such a shape.

The STI liner 153 may be formed along the side walls and the bottom surface of the STI trench 151 in a conformal manner. The STI liner 153 may include a material different from the device isolation film 155. For example, the STI liner 153 may include silicon nitride (SiN) and may include a material having an etching ratio different form the device isolation film 155. Although it is not clearly illustrated in the drawings, the STI liner 153 may include a double film structure which includes silicon oxide film (SiO₂) and silicon nitride (SiN). Specifically, the silicon oxide film (SiO₂) may be located on the silicon nitride (SiN). However, the present inventive concept is not limited thereto and vice versa.

Thus, the STI liner 153 may possibly prevent the device isolation film 155 from being etched together in the process for epitaxially growing the sources or the drains 161, 163, 165. Furthermore, the STI liner 153 may be formed to have a thickness of 40 Å to 150 Å, but the present inventive concept is not limited thereto.

The device isolation film 155 may be formed on the STI liner 153 and may fill up at least a part of the STI trench 151. The device isolation film 155 may be formed inside the STI liner 153 and may be in contact with the inner wall and the bottom surface of the STI liner 153. The upper surface of the device isolation film 155 may be located on the same plane as the upper surface of the substrate 100. However, the present inventive concept is not limited thereto.

The gate structures G1 and G2 of the present inventive concept may include gate insulating films 133 and 143, gate electrodes 135 and 145, and spacers 131, 132, 141, and 142. The gate structures G1 and G2 may include a first gate structure G1 and a second gate structure G2. The gate structures G1 and G2 of the present inventive concept may be formed by a gate last manufacturing process.

The first gate structure G1 may be disposed on the active region 110, and the second gate structure G2 may be disposed on the device isolation film 155. The first gate structure G1 may be formed by the substantially same manner as the second gate structure G2. The first gate structure G1 will be mainly described in detail.

The gate insulating film 133 may be disposed between the substrate 100 and the gate electrode 135. The gate insulating film 133 may include a high dielectric constant (high-K) film. When the gate insulating film 133 is a high dielectric constant film, the gate insulating film 133 may be made up of a material having a high dielectric constant. In some embodiments of the present inventive concept, as the material having the high dielectric constant, for example, HfO₂, Al₂O₃, ZrO₂, TaO₂ or the like may be used, but the present inventive concept is not limited thereto.

Although it is not illustrated in detail, an interface film (not illustrated) serving to reduce or possibly prevent the defective interface between the gate insulating film 133 and the substrate 100 may also be further disposed between the gate insulating film 133 and the substrate 100. The interface film (not illustrated) may include a low dielectric material layer having a dielectric constant k of 9 or less, for example, a silicon oxide film (k is about 4) or a silicon oxynitride film (k is about 4 to 8 depending on the contents of oxygen atoms and nitrogen atoms). Otherwise, the interface film (not illustrated) may be made up of silicate and may be made up of a combination of the films illustrated above.

The gate electrode 135 may include a conductive material. In some embodiments of the present inventive concept, the gate electrode 135 may include metal layers MG1, MG2. As illustrated, the gate electrode 135 may be formed by lamination of two or more metal layers MG1, MG2. The metal layer MG1 serves to adjust the work function, and the second metal layer MG2 serves to fill the space formed by the metal layer MG1. For example, the first metal layer MG1 may include at least one of TiN, TaN, TiC and TaC. Further, the second metal layer MG2 may include W or Al. Otherwise, the gate electrode 135 may be made up of Si, SiGe or the like rather than the metal. The gate electrode 135, for example, may be formed through the replacement process, but is not limited thereto.

The spacers 131 and 132 may be disposed on at least one side of the gate electrode 135. Specifically, as illustrated in FIG. 2, the spacers 131 and 132 may be disposed on both sides of the gate electrode 135. The spacers 131 and 132 may include at least one of a nitride film and an oxynitride film. In FIG. 2, the each side of the spacers 131 and 132 is illustrated as curved line, respectively. However, the present inventive concept is not limited thereto. The shapes of the spacers 131 and 132 may be deformed in various manners unlike this shape. For example, in some embodiments of the present inventive concept, the shapes of the spacers 131 and 132 may be deformed into an I-shape or an L-shape unlike the illustrated shapes.

The sources or drains 161 and 163 may be formed in the active region 110 between the adjacent gate structures (e.g., G1 and G2). Specifically, the sources or drains 161 and 163 may be formed on at least one side of the first gate structure G1. The sources or drains 161 and 163 may be formed so as to be in contact with the outer surface of the STI liner 153.

Also, the sources or drains 161 and 163 may be formed so as to be in contact with a part of the lower surface of the first gate structure G1 or so as to overlap the first gate structure G1. That is, the lower surfaces of the spacers 131 and 132 and the upper surfaces of the sources or drains 161 and 163 may be partially in contact with each other, and a part of the sources or drains 161 and 163 may be located at the lower part of the first gate structure G1. However, the present inventive concept is not limited thereto.

The sources or drains 161 and 163 may be formed by an epitaxial growth method. Specifically, the sources or drains 161 and 163 may include silicon or germanium that is an elemental semiconductor material. Also, the sources or drains 161 and 163 may include a compound semiconductor and, for example, may include a group IV-IV compound semiconductor or a group III-V compound semiconductor. Specifically, when taking the group IV-IV compound semiconductor as an example, the epitaxial layer may be a binary compound, a ternary compound including at least two or more of carbon (C), silicon (Si), germanium (Ge) and tin (Sn), or a compound in which these compounds are doped with a group IV element. When taking the group III-V compound semiconductor as an example, the epitaxial layer may be one of a binary compound, a ternary compound or a quaternary compound formed by binding at least one of aluminum (Al), gallium (Ga) and indium (In) as a group III element with one of phosphide (P), arsenic (As) and antimonium (Sb) as a group V element. Although it is not illustrated in the drawings, the sources or drains 161 and 163 may be formed by an LDD structure. However, the present inventive concept is not limited thereto.

The interlayer insulating film 105 may be formed on the substrate 100. The interlayer insulating film 105 may be formed so as to cover the gate structures G1 and G2, or may be formed between the gate structures G1 and G2. The interlayer insulating film 105 may take charge of the electrical insulation of the semiconductor elements at the bottom of the interlayer insulating film 105 and the semiconductor element at the top of the interlayer insulating film 105. The interlayer insulating film 105 may be formed using silicon oxides, such as borosilicate glass (BSG), phosphosilicate glass (PSG), borophosphosilicate glass (BPSG), undoped silicate glass (USG), tetraethylorthosilicate glass (TEOS) or high density plasma-CVD (HDP-CVD). However, the present inventive concept is not limited thereto.

The second gate structure G2 includes a gate insulating film 143 being in contact with the device isolation film 155, a gate electrode 145 located on the gate insulating film 143, and spacers 141 and 142 disposed on either side of the gate electrode 145.

The lower surface of the second gate structure G2 may be in contact with the upper surfaces of the device isolation film 155 and the STI liner 153. That is, the lower surfaces of the spacers 141 and 142 of the second gate structure G2 may be formed so as to be in contact with the upper surface of the STI liner 153. Specifically, the spacers 141 and 142 may include a first spacer part 141 formed on one side of the gate electrode 145, and a second spacer part 142 formed on the other side of the gate electrode 145. At this time, the first spacer part 141 may be in contact with a first upper surface of the STI liner 153, and the second spacer part 142 may be in contact with a second upper surface spaced apart from the first upper surface of the STI liner 153. That is, the entire STI liner 153 may be located in the lower part of the second gate structure G2 and overlapped. However, the present inventive concept is not limited thereto, and only a part of the STI liner 153 may be located in the lower part of the second gate structure G2 and overlapped.

It is possible to include a process of removing native oxide formed in the substrate 100 during the epitaxial process for forming the sources or drains 161, 163, 165. In the process of removing the oxide removal, the spacers 141 and 142 of the second gate structure G2 and the STI liner 153 are in contact with each other, which may make it possible to prevent the device isolation film 155 from being etched together with the native oxide. Thus, it is possible to reduce or possibly prevent an occurrence of defect such as current leakage in the semiconductor device 1 of the present inventive concept.

Also, the facet of the sources or drains 161, 163, and 165 may have a shape as illustrated in FIG. 2. However, although it is not clearly illustrated in the drawings, a part of the STI liner 153 may also be etched together in the etching process of the native oxide. However, the present inventive concept is not limited thereto.

Referring to FIG. 3, a part of the sources or drains 161, 163, and 165 has an upper surface higher than the upper surface of the device isolation film 155. The sources or drains 161, 163, and 165 may be grown to have a uniform thickness in the process of epitaxial growth. Thus, the first portions of the sources or drains 161, 163, and 165 may be formed higher than the upper surface of the substrate 100, and the second portions thereof may be formed lower than the upper surface of the substrate 100. At this time, the second portion may be disposed adjacent to the STI liner 153 than the first portion. Thus, the facet of the sources or drains 161, 163, and 165 may have a shape as illustrated in FIG. 3. However, FIG. 3 corresponds to an embodiment of the present inventive concept, and the present inventive concept is not limited thereto.

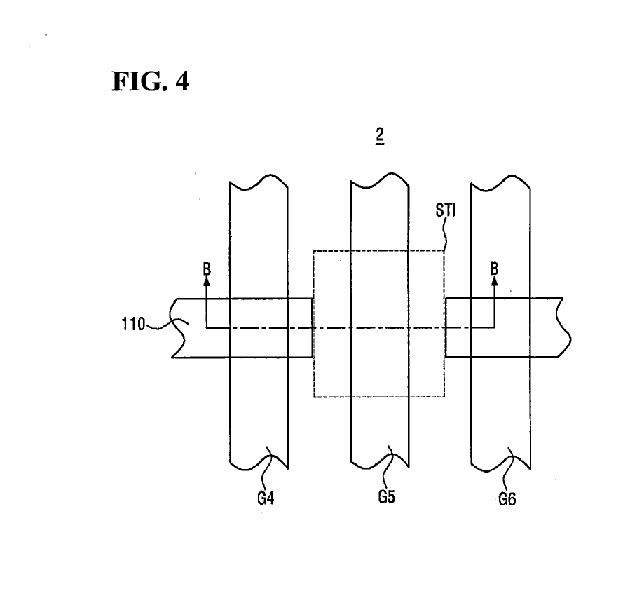

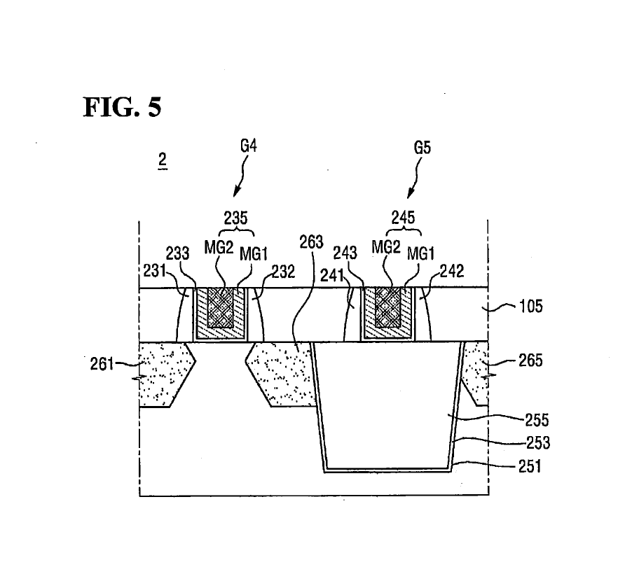

FIG. 4 is a diagram for explaining a semiconductor device according to a second embodiment of the present inventive concept. FIG. 5 is a cross-sectional view taken along a line B-B of FIG. 4. For convenience of explanation, hereinafter, the repeated description of the same matters as the previous embodiment will not be provided, and the description will be provided while focusing on the differences.

Referring to FIGS. 4 and 5, a semiconductor device 2 according to a second embodiment of the present inventive concept may be formed in the substantially similar manner to the semiconductor device 1 according to the above-mentioned first embodiment of the present inventive concept. The first gate structure G4 may be disposed on the active region 110, and the second gate structure G5 may be disposed on a device isolation film 255.

However, the second gate structure G5 of the semiconductor device 2 according to the second embodiment may be disposed so as to be in contact with only the upper surface of the device isolation film 255 without being in contact with the upper surface of the STI liner 253. That is, the width of the device isolation film 255 may be formed to be further larger than the width of the gate structure G5, and the entire second gate structure G5 may be disposed so as to overlap the element isolation film 255. In other words, the spacers 241 and 242 included in the second gate structure G5 may be disposed so as not to be in contact with the STI liner 253. The lower surfaces of the spacers 241 and 242 may be formed so as to be in contact with only the upper surface of the single device isolation film 255.

Even in such a case, it may be possible to prevent the device isolation film 255 located in the STI liner 253 from being etched with the native oxide, in the process of removing the native oxide formed in the substrate 100 during the epitaxial process for forming the sources or drains 261, 263, and 265. That is, the STI liner 253 of the present inventive concept may reduce or possibly prevent an occurrence of defect such as current leakage in the semiconductor device 2 of the present inventive concept.

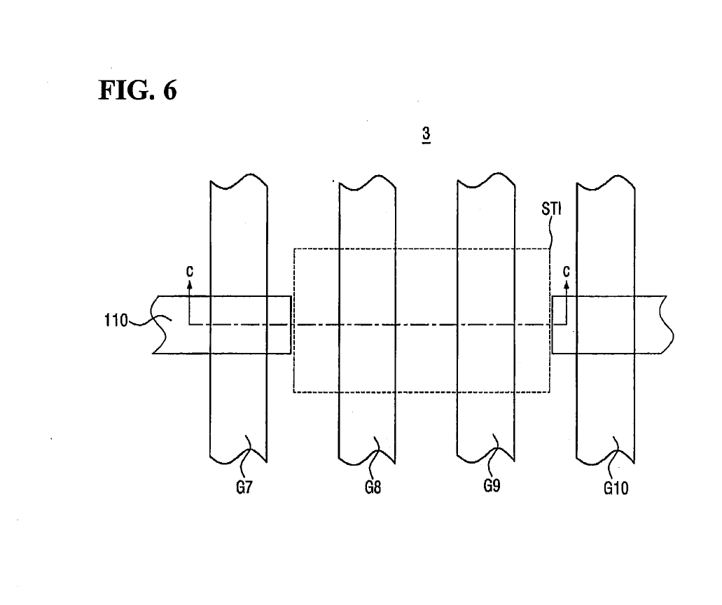

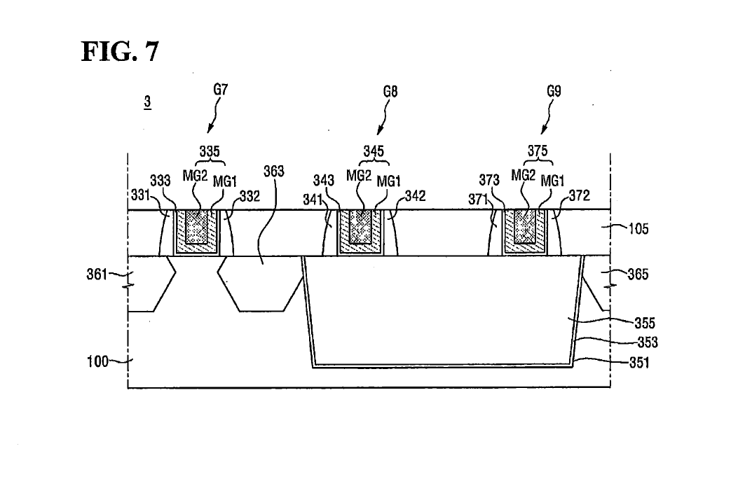

FIG. 6 is a diagram for explaining a semiconductor device according to a third embodiment of the present inventive concept. FIG. 7 is a cross-sectional view taken along a line C-C of FIG. 6. For convenience of explanation, hereinafter, the repeated description of the same matters as the previous embodiment will not be provided, and the description will be provided while focusing on the differences.

Referring to FIGS. 6 and 7, a semiconductor device 3 according to the third embodiment of the present inventive concept may be formed in the substantially similar manner to the above-mentioned semiconductor device 1 according to the second embodiment of the present inventive concept. However, the semiconductor device 3 according to the third embodiment may further include a third gate structure G9.

At this time, the first gate structure G7 may be disposed on the active region 110, and the second gate structure G8 and the third gate structure G9 may be disposed on a device isolation film 355. The first to third gate structures G7, G8, and G9 may be formed in the substantially same manner.

The lower surface of the third gate structure G9 may be disposed so as to be in contact with the upper surface of the device isolation film 355. The second gate structure G8 and the third gate structure G9 may be disposed on the same isolation film 355. The second gate structure G8 and the third gate structure G9 may be disposed so as to be spaced apart from each other.

Even in the semiconductor device 3 according to the third embodiment of the present inventive concept, the STI liner 353 may possibly prevent the device isolation film 355 from being etched at the boundary between the device isolation film 355 and the active region 110 during the epitaxial process for forming the sources or drains 361, 363, 365.

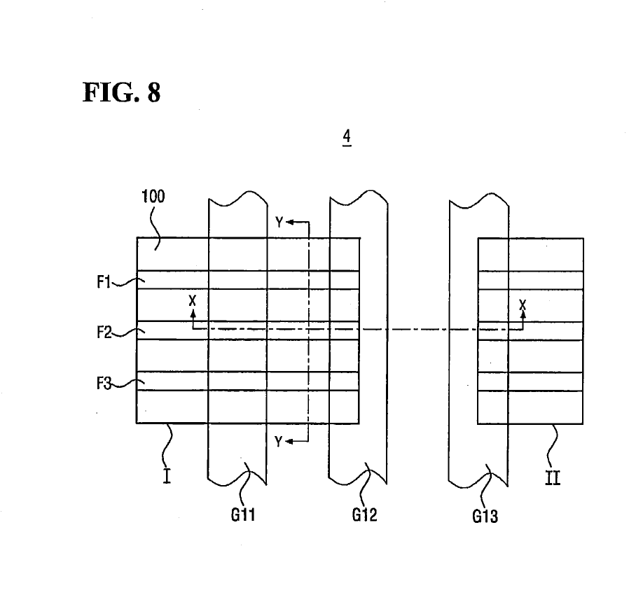

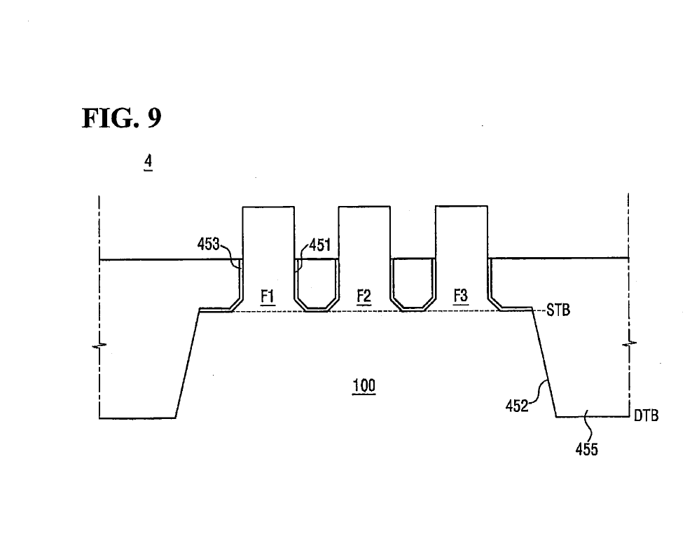

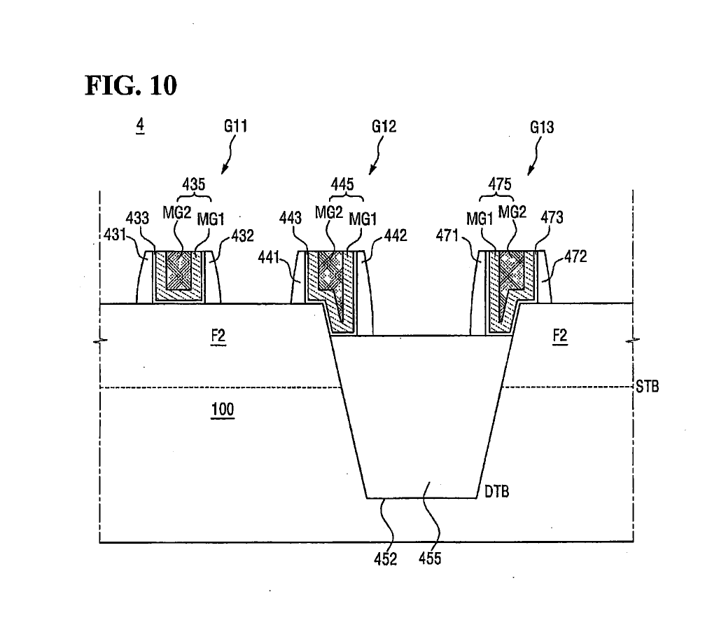

FIG. 8 is a diagram for explaining a semiconductor device according to a fourth embodiment of the present inventive concept. FIG. 9 is a cross-sectional view taken along a line Y-Y of FIG. 8. FIG. 10 is a cross-sectional view taken along a line X-X of FIG. 8.

Referring to FIGS. 8 to 10, the semiconductor device 4 includes a substrate 100, a plurality of fins F1, F2, and F3, gate structures G11, G12, and G13, a STI liner 453, and a device separation 455. Specifically, the semiconductor device 4 may include a multi-gate structure (e.g., FinFET, GAA (Gate All around) structure).

Specifically, the substrate 100 may be made up of one or more semiconductor materials selected from a group that consists of Si, Ge, SiGe, GaP, GaAs, SiC, SiGeC, InAs and InP. Further, a SOI (silicon on insulator) substrate 100 may be used. The substrate 100 may include a first region I and a second region II. The first region I and the second region II may be defined by a deep trench isolation (DTI) trench 452.

A plurality of fins F1, F2, and F3 may extend along the first direction. The plurality of fins F1, F2, and F3 may be formed on the first region I and the second region II. The plurality of fins F1, F2, and F3 may be a part of the substrate 100, and may include an epitaxial layer that is grown from the substrate 100. The device isolation film 455 may cover the side surfaces of the plurality of fins F1, F2, and F3. Although it is not clearly illustrated in the drawings, an active region (not illustrated) may include each of the plurality of fins F1, F2, and F3.

In the drawings, the plurality of fins F1, F2, and F3 are illustrated as being formed in a rectangular parallelepiped shape, but is not limited thereto. That is, the plurality of fins F1, F2, and F3 may have a chamfered shape. That is, it may have a shape with rounded corners. Since the plurality of fins F1, F2, and F3 is formed along the lengthwise direction, it may include a long side and a short side. Even if the corner portions of the fins F1, F2, and F3 are formed to have a rounded shape, it is obvious that those skilled in the art to which the present inventive concept belongs may distinguish the long and short sides from each other.

The STI trench 451 may be formed among the plurality of fins F1, F2, and F3. The STI liner 453 may be formed conformally along a part of the side walls of the STI trench 451 and the bottom surface. Furthermore, the STI liner 453 may be disposed on either side of each of the plurality of fins F1, F2, and F3. That is, the STI liner 453 may surround the part of the side walls of the plurality of fins F1, F2, and F3 with a constant thickness and may also be disposed on the bottom surface between the fins (e.g., between F1 and F2). However, the present inventive concept is not limited thereto.

The upper surface of the STI liner 453 may be formed to be lower than the upper surface of the plurality of fins F1, F2, and F3. The upper surface of the STI liner 453 may be located on the same plane as the upper surface of the device isolation film 455. However, the present inventive concept is not limited thereto.

The device isolation film 455 may be formed on the STI liner 453 and may fill up at least a part of the STI trench 451. Also, the device isolation film 455 may also fill up a part of a DTI trench 452 located between the first region I and the second region II of the substrate 100. That is, the device isolation film 455 may fill up a part of the STI trench 451 and the DTI trench 452 at the same time. The upper surface of the device isolation film 455 may be formed to be lower than the upper surfaces of the plurality of fins F1, F2, and F3. The device isolation film 455, for example, may include at least one of silicon oxide, silicon nitride, silicon oxynitride and combinations thereof. However, the present inventive concept is not limited thereto.

The STI liner 453 may include the material different from the device isolation film 455. For example, it may include silicon nitride (SiN) and may include a material having an etching ratio different from the device isolation film 455. Although it is not clearly illustrated in the drawings, the STI liner 453 may include a double film structure including the silicon oxide film (SiO₂) and silicon nitride (SiN). Specifically, the silicon oxide film (SiO₂) may be located on silicon nitride (SiN). However, the present inventive concept is not limited thereto and vice versa.

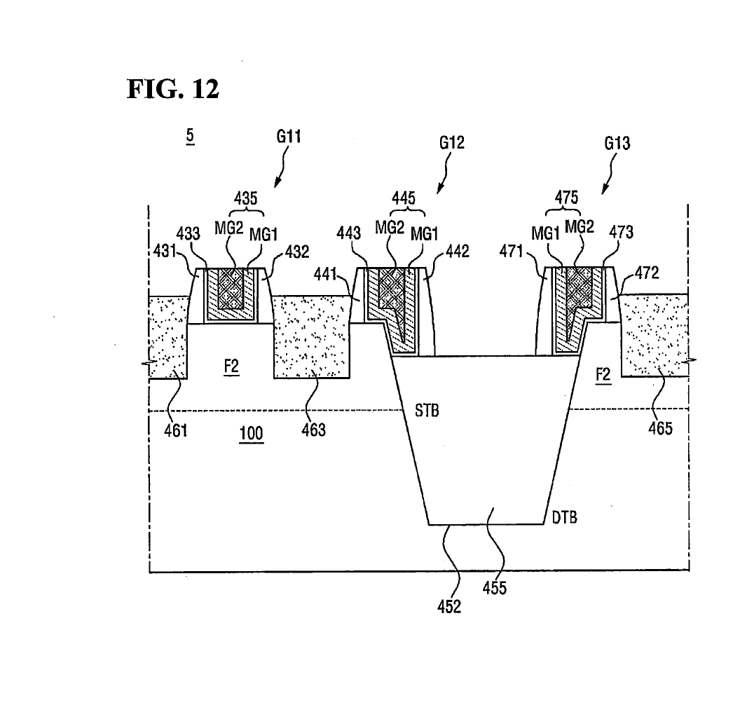

Thus, the STI liner 453 may possibly prevent the device isolation film 455 located inside the STI liner 453 from being etched together in the process of epitaxially growing the sources or drains (461, 463, and 465 of FIG. 12).

The gate structures G11, G12, and G13 may be formed on the plurality of fins F1, F2, and F3 along a second direction different from the first direction crossing the plurality of fins F1, F2, and F3. The second direction may cross the first direction. The gate structures G11, G12, and G13 may include a first gate structure G11, a second gate structure G12 and a third gate structure G13. The gate structures G11, G12, and G13 of the present inventive concept may be formed by the gate last manufacturing process. The first gate structure G11 may include a gate insulating film 433, a gate electrode 435, and spacers 431 and 432. Hereinafter, the first gate structure G11 will be mainly described in detail.

The gate insulating film 433 may be in contact with the upper surface of the device isolation film 455 and the plurality of fins F1, F2, and F3. The gate insulating film 433 may be formed on the upper surfaces of the plurality of fins F1, F2, and F3 and the upper part of the side surfaces. The gate insulating film 433 may be disposed between the gate electrode 435 and the device isolation film 455. Specifically, the gate insulating film 433 may be conformally formed along the side walls of the spacers 431, 432, the upper surface of the device isolation film 455 or the upper surfaces of the plurality of fins F1, F2, and F3. The gate insulating film 433 may include a high dielectric material having a dielectric constant higher than the silicon oxide film. For example, the gate insulating film 433 may include HfO₂, ZrO₂ or Ta₂O₅.

The gate electrode 435 may be located on the gate insulating film 433. The gate electrode 435 may include metal layers MG1, MG2 that are conformally formed along the upper surface of the gate insulating film 433. As illustrated, the gate electrode 435 may be formed by lamination of two or more metal layers MG1, MG2. The metal layer MG1 serves to adjust the work function, and the second metal layer MG2 serves to fill the space formed by the metal layer MG1. For example, the first metal layer MG1 may include at least one of TiN, TaN, TiC and TaC. Further, the second metal layer MG2 may include W or Al. Otherwise, the gate electrode 435 may be made up of Si, SiGe or the like rather than the metal. The gate electrode 435, for example, may be formed through the replacement process, but is not limited thereto.

The spacers 431 and 432 may be disposed on at least one side of the gate electrode 435. Specifically, as illustrated in FIG. 10, the spacers 431 and 432 may be disposed on both sides of the gate electrode 435. The spacers 431 and 432 may include at least one of a nitride film and an oxynitride film. In FIG. 10, the each side of the spacers 431 and 432 is illustrated as a curved line, respectively. However, the present inventive concept is not limited thereto. The shapes of the spacers 431 and 432 may be deformed in various manners unlike this shape. For example, in some embodiments of the present inventive concept, the shape of the spacers 431 and 432 may be modified into an I-shape or an L shape unlike the illustrated shape.

The first gate structure G11 may overlap the central part of the first region I. The second gate structure G12 may overlap a distal end of one side of the first region I. The third gate structure G13 may overlap a distal end of one side of the second region II. The first to third gate structures G11, G12, and G13 may be formed so as to extend in the same direction.

Further, the spacers 441 and 442 of the second gate structure G12 may include a first spacer part 441 formed on one side of the gate electrode 445, and a second spacer part 442 formed on the other side of the gate electrode 445. At this time, the first spacer part 441 is in contact with the upper surfaces of the plurality of fins F1, F2, and F3 formed in the first region I, and the second spacer part 442 may overlap only the DTI trench 452.

Similarly, the spacers 471 and 472 of the third gate structure G13 may include a first spacer part 471 formed on one side of the gate electrode 475, and a second spacer part 472 formed on the other side of the gate electrode 475. At this time, the second spacer part 472 is in contact with the upper surface of the plurality of fins F1, F2, and F3 formed in the second region II, and the first spacer part 471 may overlap only the DTI trench 452.

Although it is not clearly illustrated in the drawings, a source or drain (not illustrated) may be formed in the fins between the adjacent gate structures G11, G12, and G13. Specifically, the source or drain (not illustrated) may be formed on at least one side of the first gate structure G11.

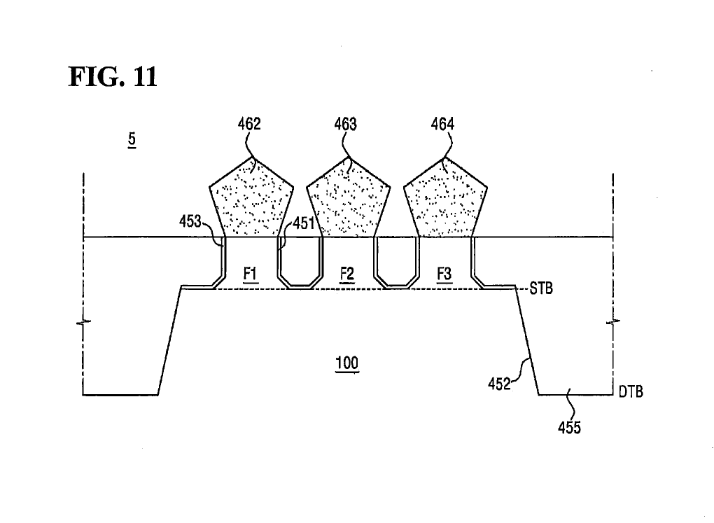

FIGS. 11 and 12 are diagrams for explaining a semiconductor device according to a fifth embodiment of the present inventive concept. For convenience of explanation, hereinafter, the repeated description of the same matters as the previous embodiment will not be provided, and the description will be provided while focusing on the differences.

Referring to FIGS. 11 and 12, a semiconductor device 5 according to a fifth embodiment of the present inventive concept may be formed in the substantially similar manner to the above-mentioned semiconductor device 4 according to the fourth embodiment of the present inventive concept. However, elevated sources or drains 461, 463, and 465 may be formed on at least one side of the gate structures G11, G12, and G13.

The elevated sources or drains 461, 463, and 465 may be formed on the plurality of fins F1, F2, and F3 on both sides of the gate electrodes G11, G12, and G13. The elevated sources or drains 461, 463, and 465 may be in contact with the side surfaces of the spacers (e.g., 431, 432) and the plurality of fins F1, F2, and F3.

The elevated sources or drains 461, 463, and 465 may be formed by the epitaxial growth method. Specifically, the elevated sources or drains 461, 463, and 465 may include silicon or germanium that is an elemental semiconductor material. Also, the sources or drains 461, 463, and 465 may include a compound semiconductor, and, for example, may include a group IV-IV compound semiconductor or a group III-V compound semiconductor.

On the other hand, the elevated sources or drains 461, 463, and 465 may have various shapes. For example, the elevated sources or drains 461, 463, and 465 may have at least one of a diamond shape, a circular shape and a rectangular shape.

When the semiconductor device 5 according to an embodiment of the present inventive concept is a PMOS transistor, the elevated sources or drains 461, 463, and 465 may include a compressive stress material. For example, the compressive stress material may be a material having a lattice constant greater than Si, and, for example, may be SiGe. The compressive stress material may improve mobility of the carrier of the channel region, by adding the compressive stress to the plurality of fins F1, F2, and F3.

On the other hand, when the semiconductor device 5 is an NMOS transistor, the elevated sources or drains 461, 463, and 465 may be the same material as the substrate 100 or a tensile stress material. For example, when the substrate 100 is Si, the elevated sources or drains 461, 463, and 465 may be Si or a material (e.g., SiC) having a lattice constant smaller than Si.

Moreover, the elevated sources or drains 461, 463, and 465 may be disposed so as to be in contact with the upper surfaces of said plurality of fins F1, F2, and F3 and so as not to be in contact with the upper surface of the STI liner 453. That is, since the epitaxial growth occurs only on the upper surfaces of the plurality of etched fins F1, F2, and F3 and the epitaxial growth does not occur on the upper surface of the STI liner 453, the elevated source drains 461, 463, 465 may be in contact with only the upper surfaces of the plurality of fins F1, F2, and F3. However, the present inventive concept is not limited thereto.

The elevated sources or drains 461, 463, and 465 may be disposed between the adjacent gate structures G11, G12, and G13 and may be in contact with the outer surfaces of the spacer (e.g., 431, 432) of the gate structures G11, G12, and G13. The upper surfaces of the elevated sources or drains 461, 463, and 465 may be formed higher than the upper surfaces of the plurality of fins F1, F2, and F3. However, the present inventive concept is not limited thereto.

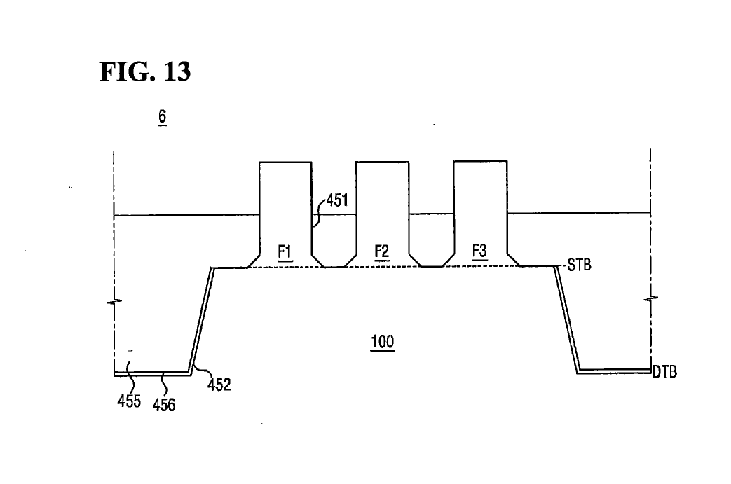

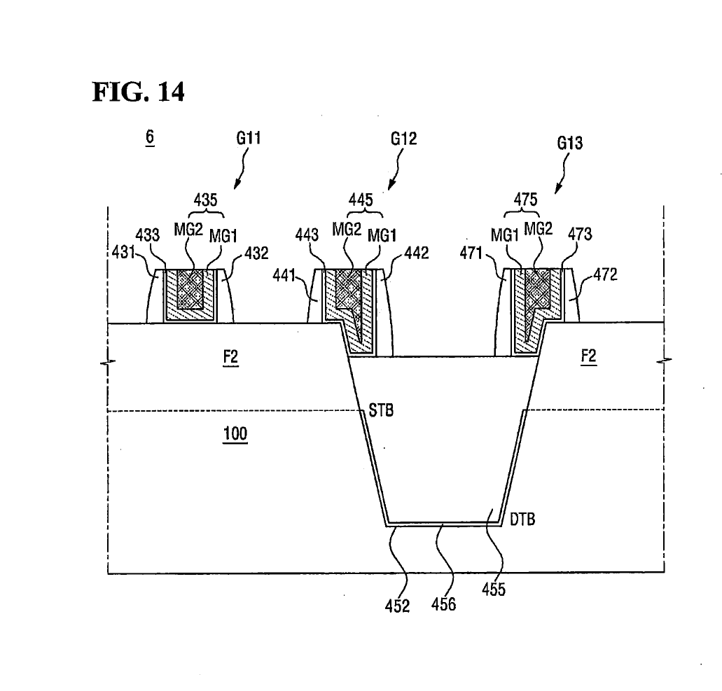

FIGS. 13 and 14 are diagrams for explaining a semiconductor device according to a sixth embodiment of the present inventive concept. For convenience of explanation, hereinafter, the repeated description of the same matters as the previous embodiment will not be provided, and the description will be provided while focusing on the differences.

Referring to FIGS. 13 and 14, the semiconductor device 6 according to the sixth embodiment of the present inventive concept may be formed in the substantially similar manner to the semiconductor device 4 according to the above-mentioned fourth embodiment of the present inventive concept. However, the semiconductor device 6 according to the sixth embodiment does not include the STI liner (453 of FIG. 9) and may include only a DTI liner 456.

Specifically, the substrate 100 includes a first region I and a second region II. The DTI trench 452 may be formed between the first region I and the second region II. The DTI liner 456 may be formed conformally along the side walls and the bottom surface of the DTI trench 452. The device isolation film 455 is formed on the DTI liner 456 and may fill up at least a part of the DTI trench 452.

The STI trench 451 may be formed among the plurality of fins F1, F2, and F3 formed in the first region I and the second region II. At this time, a lower surface STB of the STI trench 451 may be formed higher than a lower surface DTB of the DTI trench 452. However, the present inventive concept is not limited thereto. Further, the upper surface of the DTI liner 456 may be disposed on the same plane as the lower surface STB of the STI trench 451. However, the present inventive concept is not limited thereto.

The DTI liner 456 may include a material different from the device isolation film 455. For example, it may include silicon nitride (SiN) and may include a material having an etching ratio different from the device isolation film 455. However, the present inventive concept is not limited thereto, and although it is not clearly illustrated in the drawings, the DTI liner 456 may include a double film structure which includes a silicon oxide film (SiO₂) and silicon nitride (SiN).

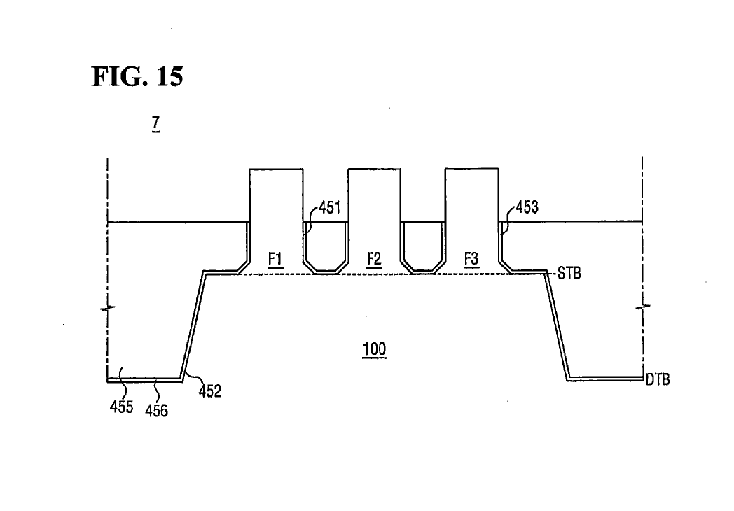

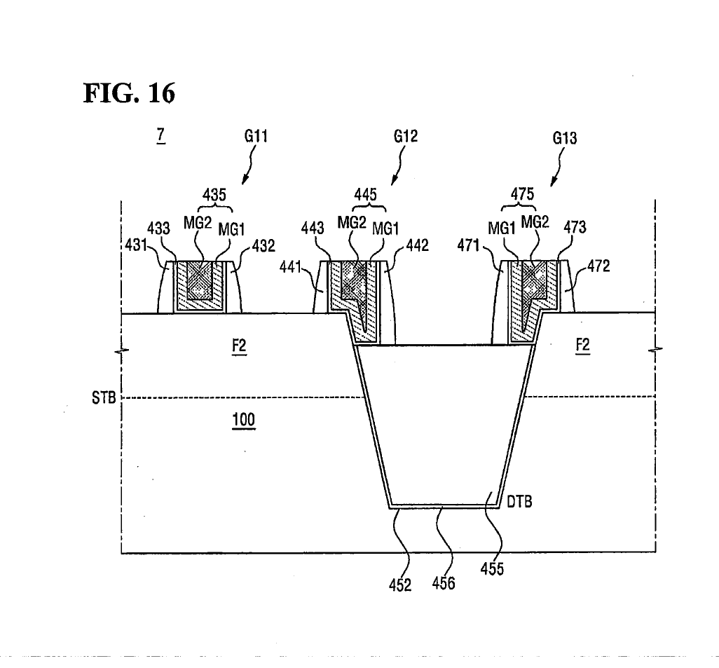

FIGS. 15 and 16 are diagrams for explaining a semiconductor device according to a seventh embodiment of the present inventive concept. For convenience of explanation, hereinafter, the repeated description of the same matters as the previous embodiment will not be described, and the description will be provided while focusing on the differences.

Referring to FIGS. 15 and 16, a semiconductor device 7 according to the seventh embodiment of the present inventive concept may be formed in the substantially similar manner to the semiconductor device 7 according to the above-mentioned fourth embodiment of the present inventive concept. However, the semiconductor device 7 according to the sixth embodiment may include both the STI liner 453 and the DTI liner 456.

The STI liner 453 may be formed conformally along the side walls and the bottom surface of the STI trench 451, and the DTI liner 456 may be formed conformally along the side walls and the bottom surface of the DTI trench 452. The STI liner 453 and the DTI liner 456 may be formed integrally with each other. The STI liner 453 and the DTI liner 456 may be formed with a constant thickness.

The STI liner 453 and the DTI liner 456 may include a material different from the device isolation film 455. For example, it may include silicon nitride (SiN) and may include a material having an etching ratio different from the device isolation film 455. Although it is not clearly illustrated in the drawings, the STI liner 453 and the DTI liner 456 may include a double film structure which includes a silicon oxide film (SiO₂) and silicon nitride (SiN). However, the present inventive concept is not limited thereto.

The STI liner 453 or the DTI liner 456 may possibly prevent the device isolation film 455 located inside the STI liner 453 or the DTI liner 456 from being etched together, in the process for epitaxially growing the sources or drains 461, 463, and 465. However, the present inventive concept is not limited thereto.

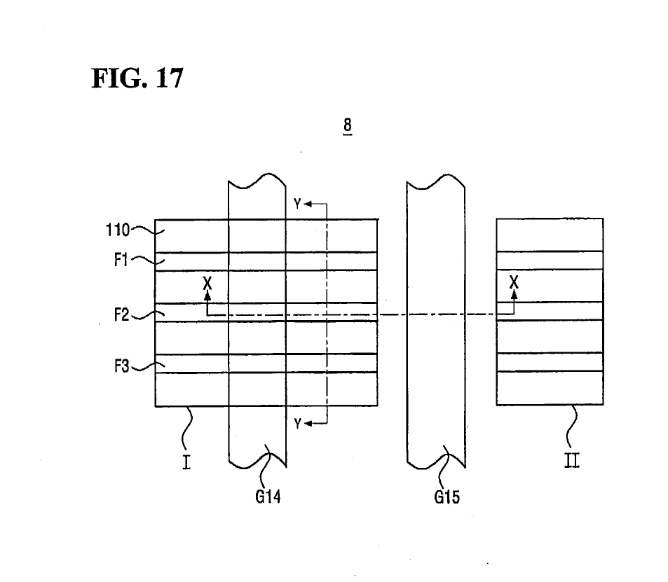

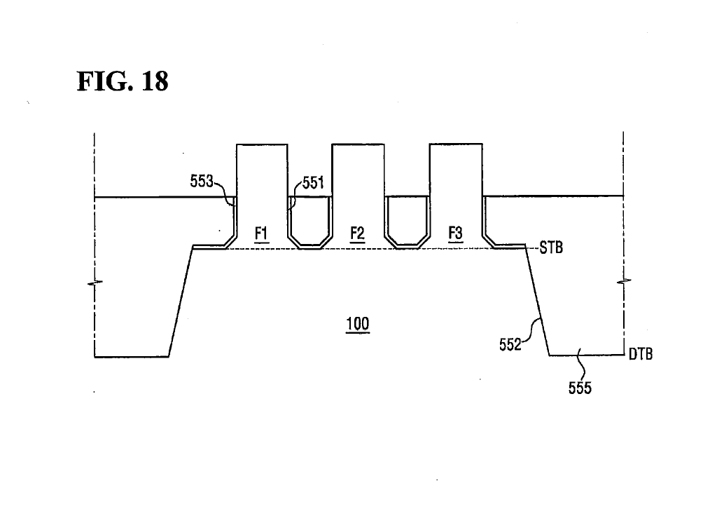

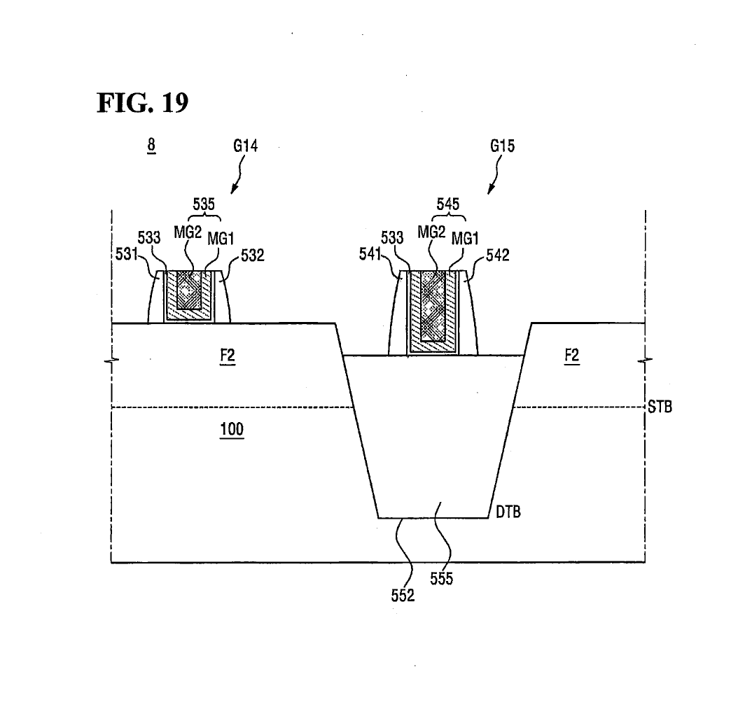

FIG. 17 is a diagram for explaining a semiconductor device according to an eighth embodiment of the present inventive concept. FIG. 18 is a cross-sectional view taken along a line Y-Y of FIG. 17. FIG. 19 is a cross-sectional view taken along a line X-X in FIG. 17. For convenience of explanation, hereinafter, the repeated description of the same matters as the previous embodiment will not be provided, and the description will be provided while focusing on the differences.

Referring to FIGS. 17 to 19, the semiconductor device 8 may include a substrate 100, a plurality of fins F1, F2, and F3, gate structures G14, G15, a STI liner 553, and a device isolation film 555. The semiconductor device 8 according to the eighth embodiment of the present inventive concept may be formed in the substantially similar manner to the semiconductor device 4 according to the above-mentioned fourth embodiment of the present inventive concept.

The plurality of fins F1, F2, and F3 may extend along the first direction. The plurality of fins F1, F2, and F3 may be formed on a first region I and a second region II. The plurality of fins F1, F2, and F3 may be a part of the substrate 100 and may include an epitaxial layer that is grown from the substrate 100. The device isolation film 555 may cover the side surfaces of the plurality of fins F1, F2, and F3.

The STI trench 551 may be formed among the plurality of fins F1, F2, and F3. The STI liner 553 may be formed conformally along a part of the side walls of the STI trench 551 and the bottom surface. Furthermore, the STI liner 553 may be disposed on both sides of each of the plurality of fins F1, F2, and F3.

The device isolation film 555 may be formed on the STI liner 553 and may fill up at least a part of the STI trench 551. Also, the device isolation film 555 may also fill up a part of the DTI trench 552 located between the first region I and the second region II of the substrate 100.

The gate structures G14, G15 may be formed on the plurality of fins F1, F2, and F3 along a second direction different from the first direction so as to intersect with the plurality of fins F1, F2, and F3. The gate structures G14 and G15 may include a first gate structure G14 and a second gate structure G15. The first gate structure G14 may include a gate insulating film 533, a gate electrode 535, and spacers 531, 532.

At this time, the first gate structure G14 may overlap the first region I, and the second gate structure G15 may not overlap the first region I. In other words, the first gate structure G14 may overlap the plurality of fins F1, F2, and F3. The second gate structure G15 may overlap the device isolation film 555 and may not overlap the plurality of fins F1, F2, and F3.

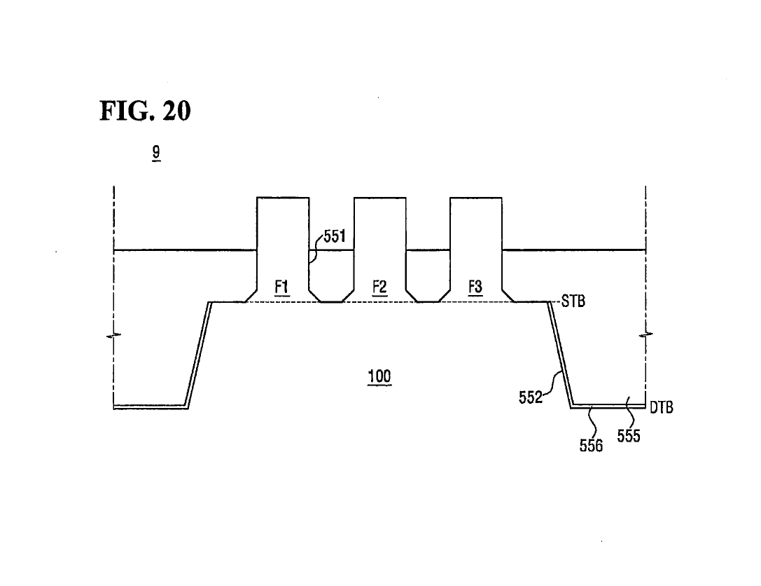

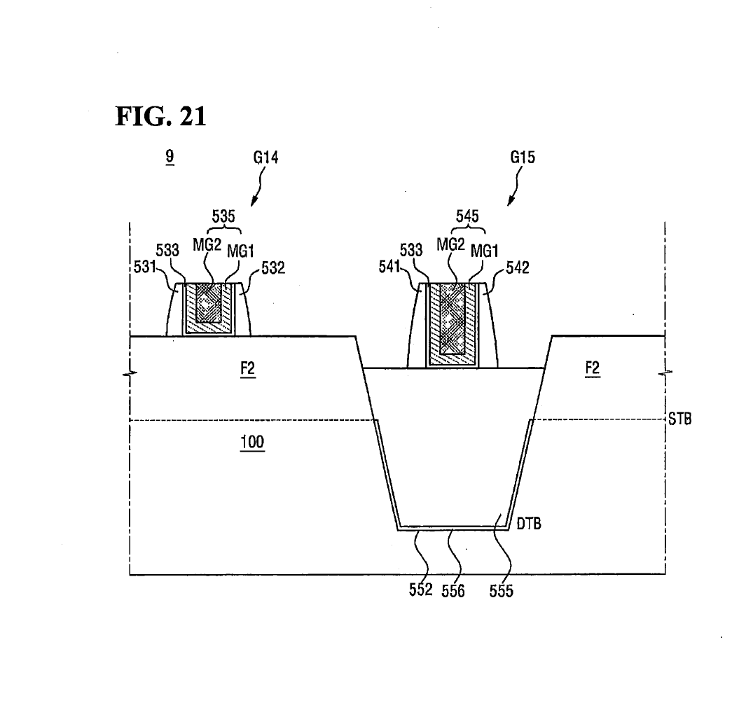

FIGS. 20 and 21 are diagrams for explaining a semiconductor device according to a ninth embodiment of the present inventive concept. For convenience of explanation, hereinafter, the repeated description of the same matters as the previous embodiment will not be provided, and the description will be provided while focusing on the differences.

Referring to FIGS. 20 and 21, a semiconductor device 9 according to the ninth embodiment of the present inventive concept may be formed in the substantially same manner as the semiconductor device 8 according to the above-mentioned eighth embodiment of the present inventive concept. However, the semiconductor device 9 according to the ninth embodiment does not include the STI liner 553 and may include only the DTI liner 556.

Specifically, the substrate 100 includes a first region I and a second region II. The DTI trench 552 may be formed between the first region I and the second region II. The DTI liner 556 may be formed conformally along the side walls and the bottom surface of the DTI trench 552. The device isolation film 555 may be formed on the DTI liner 556 and may fill up at least a part of the DTI trench 552.

The STI trench 551 may be formed among the plurality of fins F1, F2, and F3 formed in the first region I and the second region II. At this time, the lower surface STB of the STI trench 551 may be formed higher than the lower surface DTB of the DTI trench 552. However, the present inventive concept is not limited thereto. The upper surface of the DTI liner 556 may be disposed on the same plane as the lower surface STB of the STI trench 551. However, the present inventive concept is not limited thereto.

The DTI liner 556 may include a material different from the device isolation film 555. For example, it may include silicon nitride (SiN). Although it is not clearly illustrated in the drawings, the DTI liner 556 may include a double film structure which includes a silicon oxide film (SiO₂) and silicon nitride (SiN). However, the present inventive concept is not limited thereto.

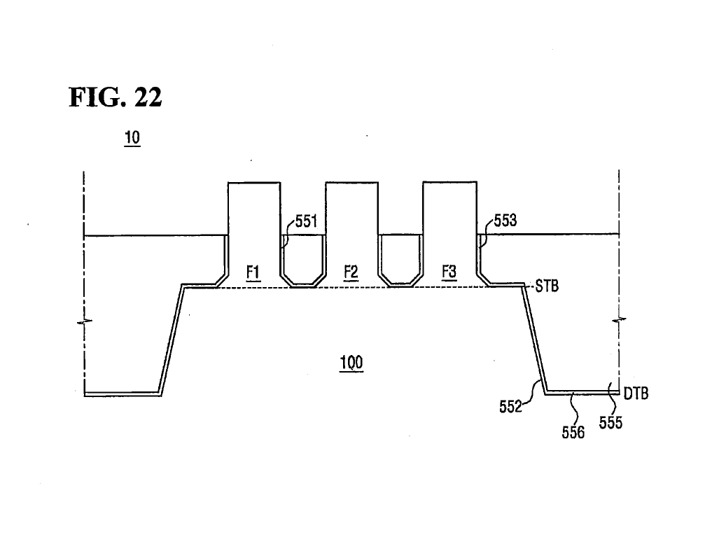

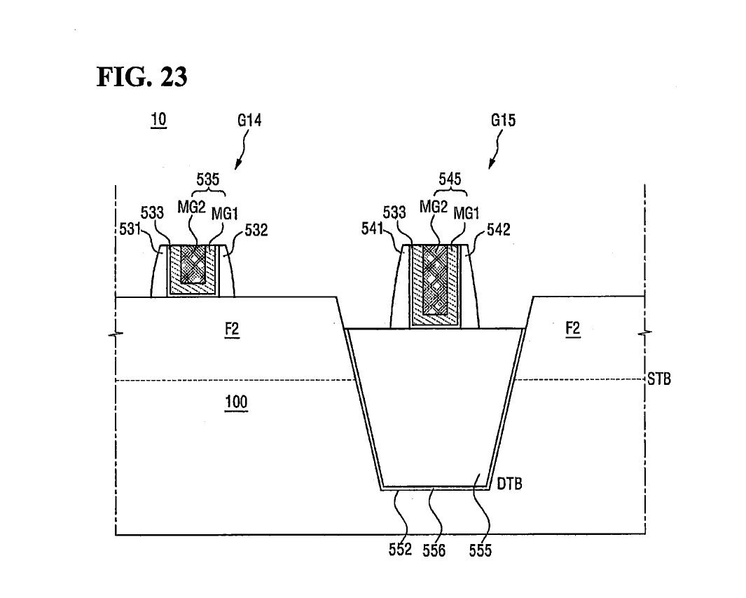

FIGS. 22 and 23 are diagrams for explaining a semiconductor device according to a tenth embodiment of the present inventive concept. For convenience of explanation, hereinafter, the repeated description of the same matters as the previous embodiment will not be provided, and the description will be provided while focusing on the differences.

Referring to FIGS. 22 and 23, a semiconductor device 10 according to a tenth embodiment of the present inventive concept may be formed in the substantially similar manner to the semiconductor device 8 according to the above-mentioned eighth embodiment of the present inventive concept. However, the semiconductor device 10 according to the tenth embodiment may include both the STI liner 553 and the DTI liner 556.

The STI liner 553 may be formed conformally along the side walls and the bottom surface of the STI trench 551, and the DTI liner 556 may be formed conformally along the side walls and the bottom surface of the DTI trench 552. The STI liner 553 and the DTI liner 556 may be formed integrally with each other. The STI liner 553 and the DTI liner 556 may be formed with a constant thickness.

The STI liner 553 and the DTI liner 556 may include a material different from the device isolation film 555. For example, it may include silicon nitride (SiN) and may include a material having an etching ratio different from the device isolation film 555. Although it is not clearly illustrated in the drawings, the STI liner 553 and the DTI liner 556 may include a double film structure which includes a silicon oxide film (SiO₂) and silicon nitride (SiN).

The STI liner 553 or the DTI liner 556 may possibly prevent the device isolation film 555 located inside the STI liner 553 or the DTI liner 556 from being etched together in the process for epitaxially growing the source or drain (not illustrated). However, the present inventive concept is not limited thereto.

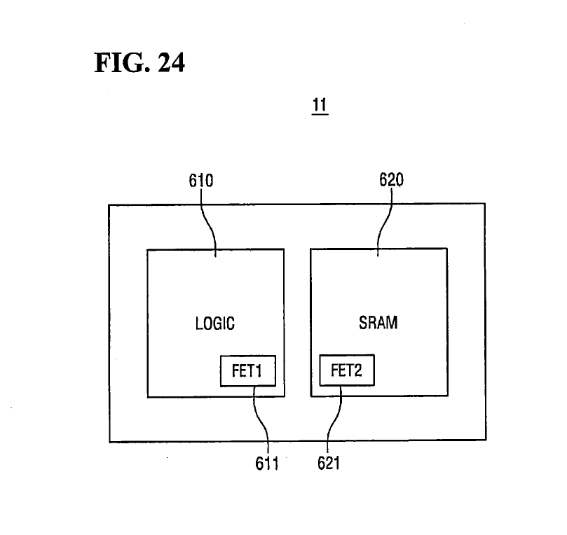

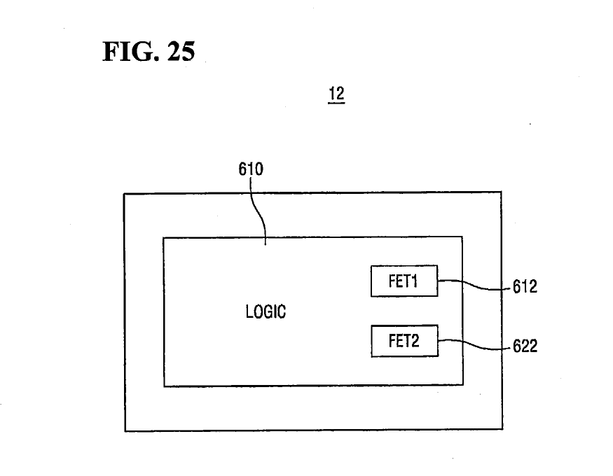

FIG. 24 is a diagram for explaining a semiconductor device according to some embodiments of the present inventive concept. FIG. 25 is a diagram for explaining a semiconductor device according to some embodiments of the present inventive concept. Hereinafter, the repeated description of the above-mentioned embodiments will not be provided, and the description will be provided while focusing on the differences.

First, referring to FIG. 24, the semiconductor device 11 may include a logic region 610 and a SRAM-forming region 620. An eleventh transistor 611 may be disposed in the logic region 610, and a twelfth transistor 621 may be disposed in the SRAM-forming region 620.

In some embodiments of the present inventive concept, the conductivity of the eleventh transistor 611 may be different from that of the twelfth transistor 621. Also, in some embodiments of the present inventive concept, the conductivity of the eleventh transistor 611 may be the same as that of the twelfth transistor 621. Thus, for example, as at least one of the eleventh transistor 611 or the twelfth transistor 621, it is possible to adopt any one of the semiconductor devices 1 to 10 according to the above-mentioned embodiments of the present inventive concept.

Next, referring to FIG. 25, the semiconductor device 12 includes the logic region 610, and thirteen and fourteen transistors 612 and 622 different from each other may be disposed in the logic region 610. Meanwhile, although it is not separately illustrated, the thirteen and fourteen transistors 612 and 622 different from each other may also be disposed in the SRAM region. Thus, for example, as at least one of the eleventh transistor 611 or the twelfth transistor 621, it is possible to adopt any one of the semiconductor devices 1 to 10 according to the above-mentioned embodiments of the present inventive concept.

Meanwhile, FIG. 25 illustrates the example logic region 610, but is not limited thereto. For example, the present inventive concept may also be applied to the logic region 610 and a region (e.g., DRAM, MRAM, RRAM, PRAM) in which another memory is formed.

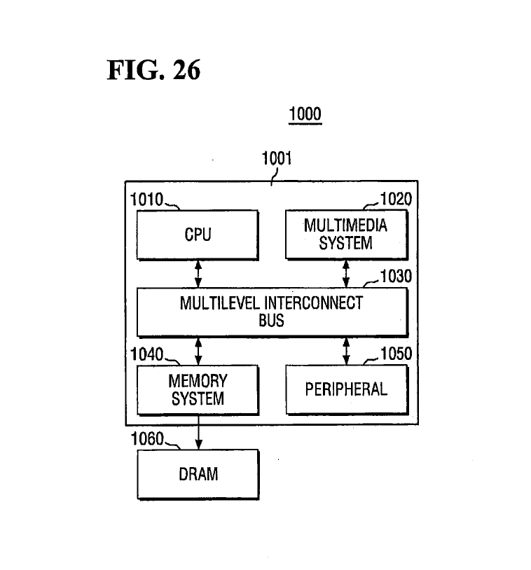

FIG. 26 is a block diagram of a SoC system which includes a semiconductor device according to some embodiments of the present inventive concept.

Referring to FIG. 26, the SoC system 1000 includes an application processor 1001, and a DRAM 1060.

The application processor 1001 may include a central processing unit 1010, a multimedia system 1020, a bus 1030, a memory system 1040, a peripheral circuit 1050 and the like.

The central processing unit 1010 is able to perform the operation that is necessary to drive the SoC system 1000. In some embodiments of the present inventive concept, the central processing unit 1010 may be configured in a multi-core environment that includes a plurality of cores.

The multimedia system 1020 may be used to perform a variety of multimedia functions in the SoC system 1000. Such a multimedia system 1020 may include a 3D engine module, a video codec, a display system, a camera system, a post-processor and the like.

The bus 1030 may be used to perform the mutual data communication among the central processing unit 1010, the multimedia system 1020, the memory system 1040 and the peripheral circuit 1050. In some embodiments of the present inventive concept, the bus 1030 may have a multilayer structure. Specifically, as examples of the bus 1030, it is possible to use a multi-layer AHB (multi-layer Advanced High-performance Bus) or a multi-layer AXI (multi-layer Advanced Extensible Interface), but the invention is not limited thereto.

The memory system 1040 may provide an environment that is necessary for the application processor 1001 to be connected to an external memory (e.g., DRAM 1060) and operated at a high speed. In some embodiments of the present inventive concept, the memory system 1040 may include another controller (e.g., a DRAM controller) for controlling an external memory (e.g., a DRAM 1060).

The peripheral circuit 1050 may provide an environment that is necessary for the SoC system 1000 to be more smoothly connected to an external device (e.g., a main board). Thus, the peripheral circuit 1050 may be provided with various interfaces which make the external device connected to the SoC system 1000 compatible.

The DRAM 1060 may function as an operation memory which is required for the operation of the application processor 1001. In some embodiments of the present inventive concept, as illustrated, the DRAM 1060 may be located outside the application processor 1001. Specifically, the DRAM 1060 may be packaged with the application processor 1001 in the form of PoP (Package on Package).

As at least one of the components of the system SoC 1000, it is possible to adopt any one of the semiconductor devices 1 to 12 according to the above-mentioned embodiments of the present inventive concept.

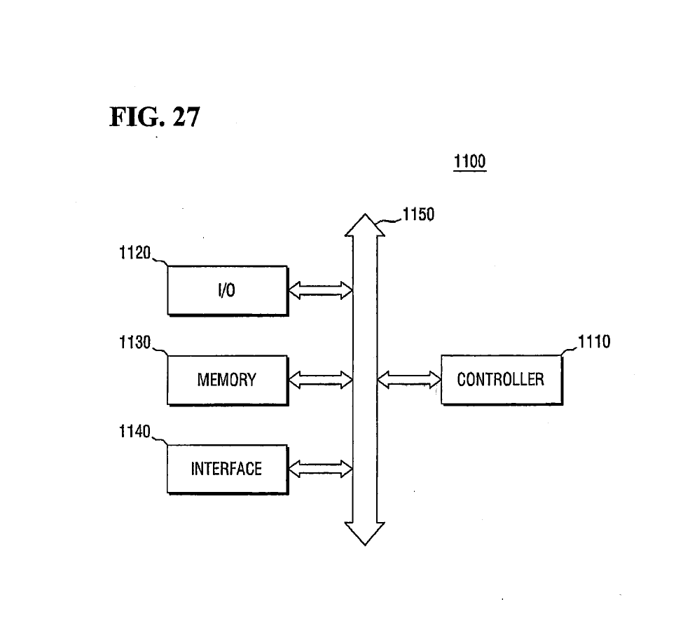

FIG. 27 is a block diagram of an electronic system which includes the semiconductor device according to some embodiments of the present inventive concept.

Referring to FIG. 27, an electronic system 1100 according to an embodiment of the present inventive concept may includes a controller 1110, an input/output device (I/O) 1120, a memory device 1130, an interface 1140 and a bus 1150. The controller 1110, the input/output device 1120, the memory device 1130 and/or the interface 1140 may be coupled together via the bus 1150. The bus 1150 corresponds to a path through which the data are moved.

The controller 1110 may include at least one of a microprocessor, a digital signal process, a microcontroller, and logic elements capable of performing the function similar to these elements. The input/output device 1120 may include a keypad, a keyboard, a display device and the like. The memory device 1130 may store data and/or instruction words. The interface 1140 may perform the functions of transferring the data to the communication network or receiving the data from the communication network. The interface 1140 may be a wired or wireless form. For example, the interface 1140 may include an antenna or a wired and wireless transceiver.

Although it is not illustrated, the electronic system 1100 may further include a high-speed DRAM and/or SDRAM as an operation memory for improving the operation of the controller 1110. At this time, as the operation memory, it is possible to adopt the semiconductor devices 1 to 10 according to the above-mentioned embodiments of the present inventive concept. Further, the above-mentioned semiconductor devices 1 to 10 according to some embodiments of the present inventive concept may be provided inside the memory device 1130 or may be provided as a part of the controller 1110, the input/output device (I/O) 1120 or the like.

The electronic system 1100 may be applied to a personal digital assistant (PDA), a portable computer, a web tablet, a wireless phone, a mobile phone, a digital music player, a memory card or all electronic products that may transmit and/or receive information in a wireless environment.

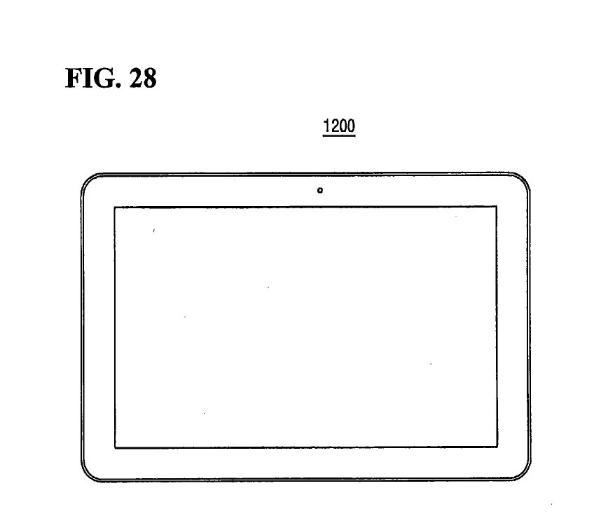

FIGS. 28 to 30 are example semiconductor systems to which the semiconductor devices according to some embodiments of the present inventive concept may be applied.

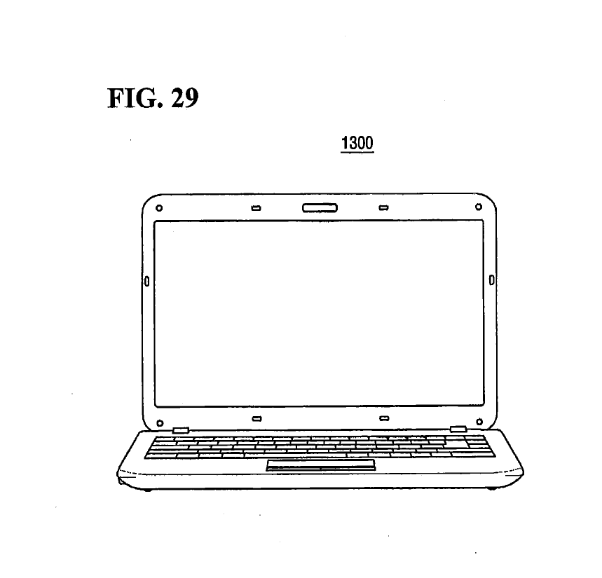

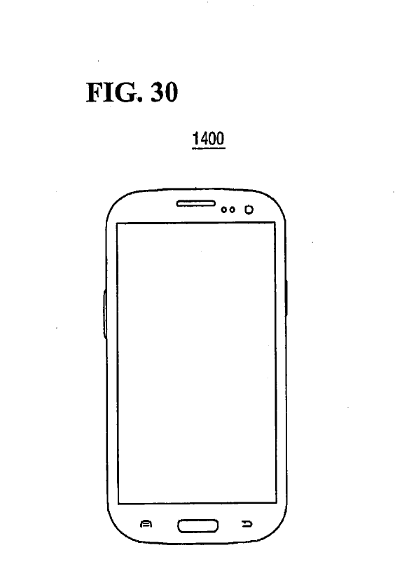

FIG. 28 is a diagram illustrating a tablet PC 1200, FIG. 29 is a diagram illustrating a laptop computer 1300, and FIG. 30 is a diagram illustrating a smart phone 1400. At least one of the semiconductor devices 1 to 12 according to some embodiments of the present inventive concept may be used in the tablet PC 1200, the laptop computer 1300, the smart phone 1400 or the like.

Further, it will be apparent to those skilled in the art that the semiconductor devices according to some embodiments of the present inventive concept may also be applied to other integrated circuit devices that are not illustrated. That is, although only the tablet PC 1200, the laptop computer 1300 and the smart phone 1400 are adopted as an example of the semiconductor system according to this embodiment above, the example of the semiconductor system according to this embodiment is not limited thereto. In some embodiments of the present inventive concept, the semiconductor system may be achieved by a computer, a ultra mobile PC (UMPC), a workstation, a net-book, personal digital assistants (PDA), a portable computer, a wireless phone, a mobile phone, an e-book, a portable multimedia player (PMP), a portable game machine, a navigation device, a black box, a digital camera, a 3-dimensional television, a digital audio recorder, a digital audio player, a digital picture recorder, a digital picture player, a digital video recorder, a digital video player or the like.

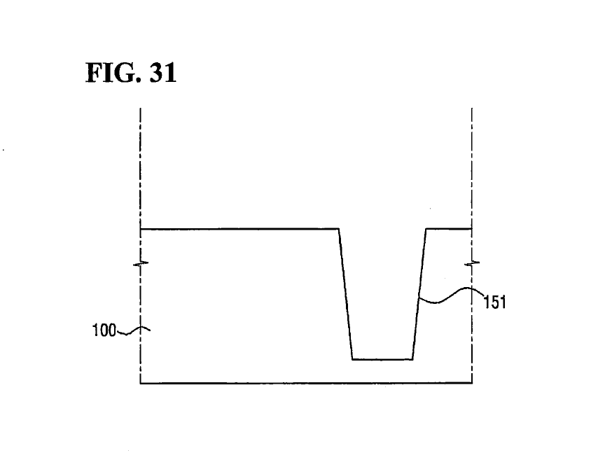

Hereinafter, a method for manufacturing the semiconductor device according to an embodiment of the present inventive concept will be described with reference to FIG. 31 to FIG. 48.

FIGS. 31 to 40 are diagrams illustrating a method of manufacturing the semiconductor device according to some embodiments of the present inventive concept.

First, referring to FIG. 31, the STI trench 151 is formed on the substrate 100. The STI trench 151 may define an active region (110 of FIG. 1) formed in the substrate 100. The STI trench 151 may be formed at a constant depth and may be formed in a tapered shape in which its width becomes wider as it goes from the top to the bottom. However, the present inventive concept is not limited to this shape.

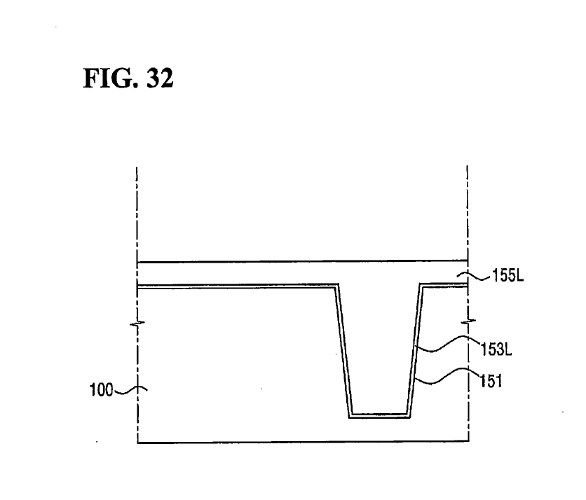

Next, referring to FIG. 32, it is possible to form the STI liner 153L and the device isolation film 155L on the substrate 100. The STI liner 153L may be formed conformally along the side walls and the bottom surface of the STI trench 151 and the upper surface of the substrate 100. The STI liner 153L may include a material different from the device isolation film 155L. For example, it may include silicon nitride (SiN). Although it is not clearly illustrated in the drawings, the STI liner 153L may include a double film structure which includes silicon oxide film (SiO₂) and silicon nitride (SiN). Specifically, the silicon oxide film (SiO₂) may be located on silicon nitride (SiN). However, the present inventive concept is not limited thereto, and vice versa.

The device isolation film 155L may be conformally formed along the upper surface of the STI liner 153L. The device isolation film 155L may include a material having an etching ratio different form the STI liner 153L.

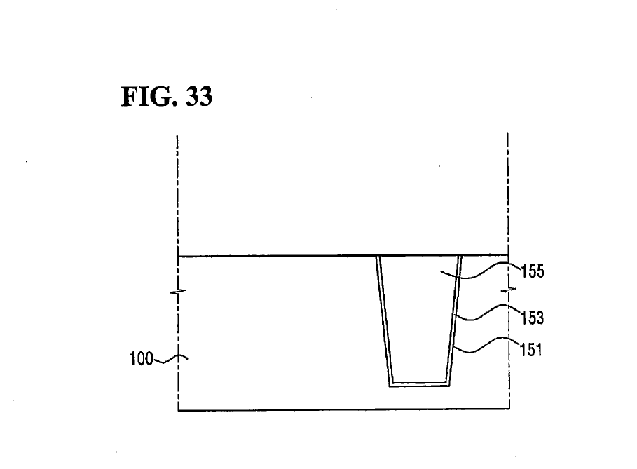

Next, referring to FIG. 33, a planarization process (e.g., a CMP process) is performed so that the upper surface of the substrate 100 is exposed. The upper surface of the STI liner 153 and the upper surface of the device isolation film 155 are located on the same plane through this process.

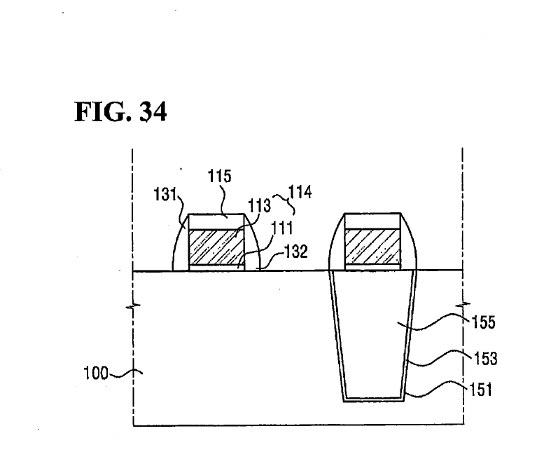

Next, referring to FIG. 34, the first gate structure G1 and the second gate structure G2 are formed. The first gate structure G1 may be disposed on the active region 110, and the second gate structure G2 may be disposed on the device isolation film 155. The first gate structure G1 may be formed in the substantially same manner as the second gate structure G2.

The first and second gate structures G1 and G2 may include a dummy gate pattern 114, a mask pattern 115, and spacers 131 and 132. The dummy gate pattern 114 includes a dummy gate insulating film 111, and a dummy gate electrode 113. The dummy gate electrode 113 may be formed on the dummy gate insulating film 111. The mask pattern 115 may be located on the dummy gate electrode 113. The mask pattern 115 is used to form the dummy gate electrode 113 and the dummy gate insulating film 111. The dummy gate insulating film 111, for example, may be a silicon oxide film, and the dummy gate electrode 113 may be polysilicon (poly-Si). However, the present inventive concept is not limited thereto.

The spacers 131 and 132 may be formed on at least one side of the dummy gate electrode 113. Specifically, the spacers 131 and 132 may be formed by performing an etch-back process after forming an insulating film (not illustrated) on a product formed with the dummy gate pattern 114. The spacers 131 and 132 may expose the upper surface of the mask pattern 115, and the upper surface of the active region 110 that does not overlap the dummy gate electrode 113. The spacers 131 and 132 may include at least one of a nitride film, and an oxynitride film.

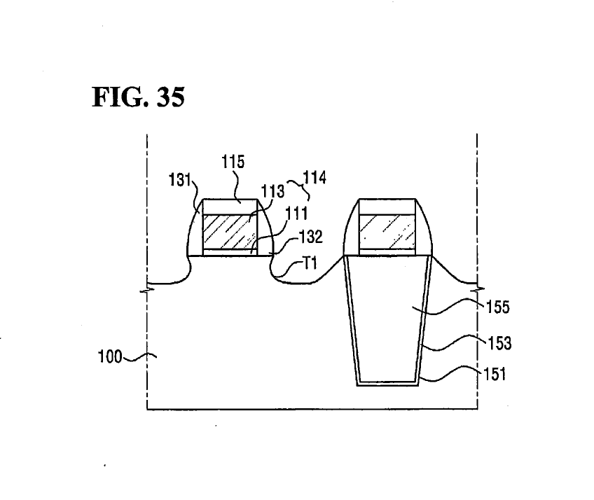

Next, referring to FIG. 35, both the first gate structure G1 and the second gate structure G2 are primarily etched to form a first trench T1. As the etching material used at this time, it is possible to a material having a selective etching ratio so as not to etch the spacers 131 and 132 or the STI liner 153. At this time, it is possible to use wet etching or dry etching. However, the present inventive concept is not limited thereto.

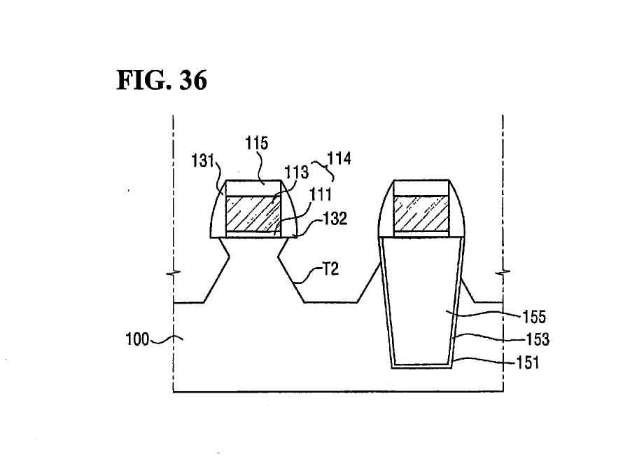

Next, referring to FIG. 36, both the first gate structure G1 and the second gate structure G2 are secondarily etched to form a second trench T2. Similarly, since a material having a selective etching ratio is used so as not to etch the spacers 131 and 132 or the STI liner 153 in the etching process, etching does not occur in the device isolation film 155 located inside the STI liner 153. That is, the STI liner 153 may possibly prevent a situation in which etching occurs in the device isolation film 155 in the primary or secondary etching process and the current leakage occurs in the transistor.

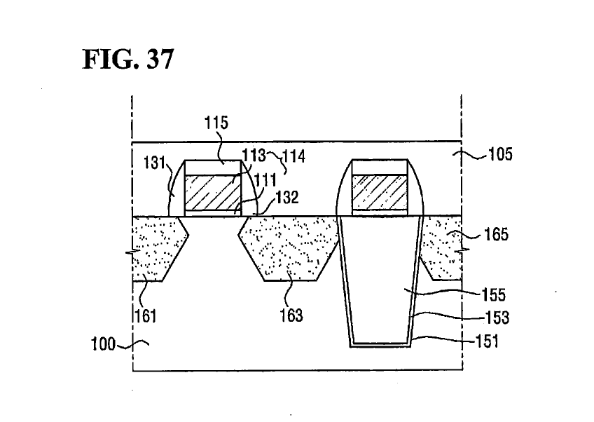

Next, referring to FIG. 37, sources and drains 161, 163, and 165 are formed on the second trench T2 using an epitaxial process. The sources or drains 161, 163, and 165 may include silicon or germanium as an elemental semiconductor material. Also, the sources or drains 161, 163, and 165 may include a compound semiconductor, and for example, may include a group IV-IV compound semiconductor or a group III-V compound semiconductor.

Although it is not clearly illustrated in the drawings, as in FIG. 3 described above, a part of the sources or drains 161, 163, and 165 may be formed higher than the upper surface of the device isolation film 155. However, the present inventive concept is not limited thereto.

Subsequently, an interlayer insulating film 105 may be formed on the gate structures G1 and G2 and the sources or drains 161, 163, and 165. The interlayer insulating film 105 may include at least one of an oxide film, a nitride film and an oxynitride film. However, the present inventive concept is not limited thereto.

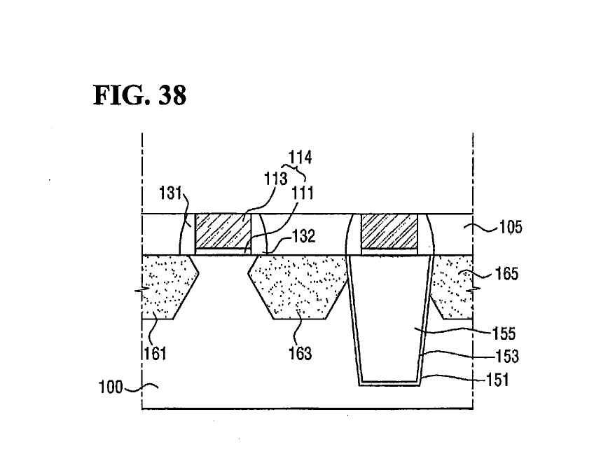

Next, referring to FIG. 38, a planarization process (e.g., a CMP process) is performed so that the upper surface of the dummy gate pattern 114 is exposed. The upper surface of the dummy gate electrode 113, the upper surfaces of the spacers 131, 132, and the upper surface of the interlayer insulating film 105 may be located on the same plane through this process.

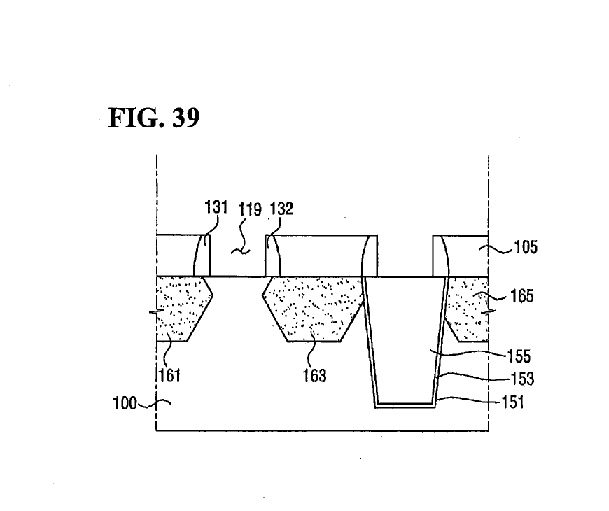

Next, referring to FIG. 39, the dummy gate pattern 114, that is, the dummy gate insulating film 111 and the dummy gate electrode 113 are removed. In some embodiments of the present inventive concept, the first etching and the second etching may be used to etch the exposed dummy gate pattern 114. Specifically, first, the exposed dummy gate pattern 114 is primarily etched using the dry etching. Moreover, next, the remaining dummy gate pattern 114 is secondarily etched using the wet etching. Thus, the entire dummy gate pattern 114 is removed, a trench 119 is formed between the spacers 131, 132, and the upper surfaces of the device isolation film 155 and the active region 110 may be exposed.

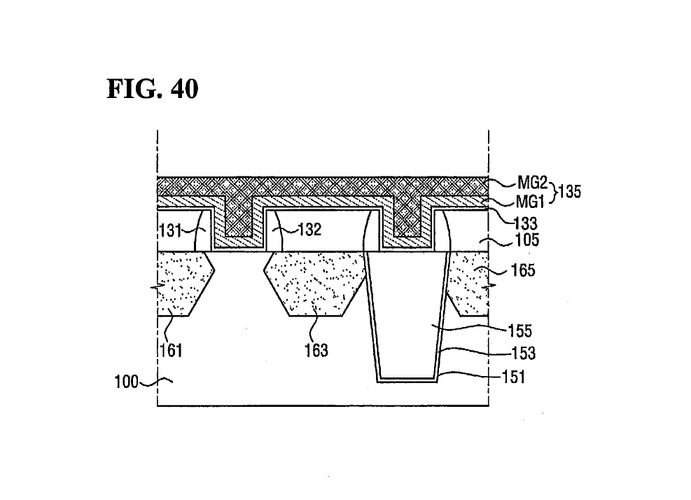

Next, referring to FIG. 40, the gate insulating film 133 is formed so as to completely cover the exposed active region 110 and the device isolation film 155. At this time, as illustrated, the gate insulating film 133 may be formed in a shape that extends upward along the side walls of the spacers 131 and 132. Further, the gate insulating film 133 may also be formed on the exposed device isolation film 155 or the exposed active region 110.

Subsequently, the gate electrode 135 is formed on the gate insulating film 133. The gate electrode 135 may include metal layers MG1, MG2. As illustrated, the gate electrode 135 may be formed by lamination of two or more metal layers MG1, MG2.

Next, referring to FIG. 2, a planarization process (e.g., a CMP process) is performed so that the upper surfaces of the spacers 131 and 132 and the interlayer insulating film 105 are exposed. Thereafter, although it is not clearly illustrated, it is possible to form another interlayer insulating film (not illustrated) on the gate structures G1 and G2 and the interlayer insulating film 105.

It possible to manufacture the semiconductor device 1 according to the first embodiment of the present inventive concept through this process. Although it is not clearly illustrated in the drawings, the semiconductor devices 2 to 10 of the second to tenth embodiments of the present inventive concept may also be manufactured using substantially the same process. However, the present inventive concept is not limited thereto.

While the present inventive concept has been particularly shown and described with reference to example embodiments thereof, it will be understood by those of ordinary skill in the art that various changes in form and details may be made therein without departing from the spirit and scope of the present inventive concept as defined by the following claims. It is therefore desired that the present embodiments be considered in all respects as illustrative and not restrictive, reference being made to the appended claims rather than the foregoing description to indicate the scope of the invention.

1. A semiconductor device comprising:
an active region on a substrate, the active region being defined by a shallow trench isolation (STI) trench;
a STI liner conformally disposed on side walls and a bottom surface of the STI trench;
a device isolation film on the STI liner, the device isolation film filling at least a part of the STI trench;
a first gate structure on the active region; and
a second gate structure spaced apart from the first gate structure,
wherein the second gate structure includes a gate insulating film being in contact with the device isolation film, a gate electrode on the gate insulating film, and spacers on both sides of the gate electrode, and
wherein lower surfaces of the spacers contact an upper surface of the STI liner.

2. The semiconductor device of claim 1, further comprising:
a source or a drain on at least one side of the first gate structure,
wherein the source or the drain contacts an outer surface of the STI liner.

3. The semiconductor device of claim 2, wherein a part of the source or the drain has an upper surface higher than an upper surface of the device isolation film.

4. The semiconductor device of claim 3, wherein a part of the source or the drain contacts a part of a lower surface of the first gate structure or overlaps the first gate structure.

5. The semiconductor device of claim 2, wherein the source or the drain is formed by an epitaxial growth method.

6. The semiconductor device of claim 1, wherein the spacers include a first spacer part on one side of the gate electrode and a second spacer part on the other side of the gate electrode, and
wherein the first spacer part contacts a first upper surface of the STI liner, and the second spacer part contacts a second upper surface of the STI liner that is spaced apart from the first upper surface of the STI liner.

7. The semiconductor device of claim 1, wherein the gate insulating film is conformally disposed along side walls of the spacers and an upper surface of the device isolation film, and
wherein the gate electrode includes a metal layer conformally disposed on an upper surface of the gate insulating film.

8. The semiconductor device of claim 1, wherein an upper surface of the device isolation film and an upper surface of the substrate are coplanar.

9. The semiconductor device of claim 1, wherein the lower surfaces of the spacers contact only an upper surface of the device isolation film.

10. The semiconductor device of claim 1, further comprising:
a third gate structure spaced apart from the second gate structure,
wherein a lower surface of the third gate structure is disposed on the device isolation film.

11. The semiconductor device of claim 1, wherein the STI liner has a double-layer structure including a silicon oxide (SiO₂) layer and a silicon nitride (SiN) layer.

12. A semiconductor device comprising:
a plurality of fins extending in a first direction on a substrate;
a first gate structure and a second gate structure extending in a second direction and being spaced apart from each other, the second direction crossing the first direction;
a shallow trench isolation (STI) trench between the plurality of fins;
a STI liner conformally disposed along a part of side walls and a bottom surface of the STI trench; and
a device isolation film on the STI liner and filling at least a part of the STI trench,
wherein the second gate structure includes a gate insulating film, a gate electrode, and spacers on both sides of the gate electrode,
wherein the spacers of the second gate structure include a first spacer part on one side of the gate electrode of the second gate structure and a second spacer part on the other side of the gate electrode of the second gate structure, and
wherein the first spacer part contacts an upper surface of at least one of the plurality of fins, and the second spacer part contacts an upper surface of the device isolation film.

13. The semiconductor device of claim 12, wherein the gate insulating film is conformally disposed along side walls of the spacers, the upper surface of the device isolation film, or upper surfaces of the plurality of fins, and
wherein the gate electrode includes a metal layer conformally disposed along an upper surface of the gate insulating film.

14. A semiconductor device comprising:
a substrate including a first region and a second region;
a plurality of fins extending in a first direction on the first region or the second region;
a shallow trench isolation (STI) trench between the plurality of fins;
a gate structure crossing the plurality of fins and extending in a second direction different from the first direction;
a deep trench isolation (DTI) trench between the first region and the second region;
a DTI liner conformally disposed along side walls and a bottom surface of the DTI trench; and
a device isolation film on the DTI liner and filling at least a part of the DTI trench,
wherein a lower surface of the STI trench is higher than a lower surface of the DTI trench.

15. The semiconductor device of claim 14, wherein an upper surface of the DTI liner and the lower surface of the STI trench are coplanar.

16. The semiconductor device of claim 14, further comprising:
a STI liner conformally disposed along side walls and a bottom surface of the STI trench,
wherein the device isolation film is disposed on the STI liner and fills at least a part of the STI trench.

17. The semiconductor device of claim 16, wherein an upper surface of the DTI liner is higher than the lower surface of the STI trench.

18. The semiconductor device of claim 16, wherein the STI liner and the DTI liner have a double film structure including a silicon oxide (SiO₂) layer and a silicon nitride (SiN) layer.

19. The semiconductor device of claim 14, wherein the gate structure includes a gate insulating film which is in contact with the device isolation film and the plurality of fins, a gate electrode on the gate insulating film, and spacers on both sides of the gate electrode,
wherein the gate insulating film is conformally disposed along side walls of the spacers, an upper surface of the device isolation film, or upper surfaces of the plurality of fins, and
wherein the gate electrode includes a metal layer conformally disposed along an upper surface of the gate insulating film.

20. The semiconductor device of claim 19, wherein the gate structure includes a first gate structure and a second gate structure,
wherein the first gate structure overlaps the plurality of fins, and
wherein the second gate structure overlaps the device isolation film and does not overlap the plurality of fins.
